(19) United States
(12) Patent Application Publication
(10) Pub. No.: US 2016/0133392 A1
(43) Pub. Date: May 12, 2016

(54) PHOTOELECTRIC CONVERSION ELEMENT AND SOLAR CELL

(71) Applicant: FUJIFILM Corporation, Tokyo (JP)

(72) Inventors: Hirotaka Sato, Ashigarakami-gun (JP); Katsumi Kobayashi, Ashigarakami-gun (JP)

(73) Assignee: FUJIFILM Corporation, Tokyo (JP)

(21) Appl. No.: 15/000,568

(22) Filed: Jan. 19, 2016

Related U.S. Application Data
(63) Continuation of application No. PCT/JP2014/069442, filed on Jul. 23, 2014.

(30) Foreign Application Priority Data
Jul. 31, 2013 (JP) 2013-159474
Jul. 8, 2014 (JP) 2014-140942

(51) Int. Cl. H01G 9/20

(52) U.S. Cl. CPC H01G 9/2009; H01G 9/2027; H01G 9/2031; H01G 9/204

(57) ABSTRACT

A photoelectric conversion element includes a first electrode which has a porous layer provided on a conductive support and a photosensitive layer having a light absorber on a surface of the porous layer, a second electrode which is opposed to the first electrode, and a solid hole transport layer which is provided between the first electrode and the second electrode. The light absorber includes a compound having a perovskite crystal structure having a cation of a group I element of the periodic table or a cation of a cationic organic group A, a cation of a metal atom M other than the group I elements of the periodic table, and an anion of an anionic atom X, and the porous layer contains at least one of insulating material. A solar cell includes this photoelectric conversion element.

### CROSS-REFERENCE TO RELATED APPLICATIONS

This application is a Continuation of PCT International Application No. PCT/JP2014/069442 filed on Jul. 23, 2014, which claims priority under 35 U.S.C §119(a) to Japanese Patent Application No. 2013-159474 filed on Jul. 31, 2013 and Japanese Patent Application No. 2014-140942 filed on Jul. 8, 2014. Each of the above application(s) is hereby expressly incorporated by reference, in its entirety, into the present application.

### BACKGROUND OF THE INVENTION

1. Field of the Invention

The present invention relates to a photoelectric conversion element and a solar cell.

2. Description of the Related Art

Photoelectric conversion elements are used in various optical sensors, copiers, solar cells, and the like. Solar cells use inexhaustible solar energy and are expected to be put into real practical use. Among these, dye-sensitized solar cells using an organic dye, a Ru bipyridyl complex, or the like as a sensitizer are actively studied and developed, and the photoelectric conversion efficiency thereof reaches about 11%.

In recent years, a study result in which a solar cell using a metal halide as a compound having a perovskite crystal structure can achieve a relatively high photoelectric conversion efficiency has been reported (see J. Phys. Chem. Lett., 2013, 4, 1532-1536) and a patent application thereof has been filed (see KR10-1172374B), whereby this result has attracted attention.

A solar cell including: a light absorption layer including a semiconductor fine particle layer and a compound having a perovskite crystal structure represented by CH₃NH₃MX₃ (M represents Pb or Sn, and X represents a halogen atom); and an electrolyte layer formed of an electrolyte is described in KR10-1172374B. In addition, a solar cell using: a compound having a perovskite crystal structure of CH₃NH₃PbI₃; and an organic hole transport material is described in J. Phys. Chem. Lett., 2013, 4, 1532-1536.

### SUMMARY OF THE INVENTION

As described above, a photoelectric conversion element and a solar cell using a compound having a perovskite crystal structure, that is a metal halide, achieve a certain result in the improvement in the photoelectric conversion efficiency. Moreover, the solar cell using a compound having a perovskite crystal structure, that is a metal halide, does not require a complicated manufacturing process, and thus the photoelectric conversion element and the solar cell may be manufactured at low cost.

However, when repeatedly manufacturing the above-described solar cell through the same manufacturing method using a compound having a perovskite crystal structure, there is a significant fluctuation in the voltage between the obtained solar cells (hereinafter, may be referred to as voltage fluctuation between solar cells), and thus stability of the cell performance is found to be insufficient.

Accordingly, an object of the invention is to provide a photoelectric conversion element which exhibits stable cell performance with less voltage fluctuation, and a solar cell including the photoelectric conversion element.

The inventors of the invention have found that in a solar cell (also referred to as perovskite-sensitized solar cell) using a compound having a perovskite crystal structure (also referred to as perovskite compound or perovskite light absorber) as a light absorber, a material which forms a porous layer as a foundation on which a photosensitive layer formed of the light absorber is provided, particularly, its electric characteristics have an influence on the voltage fluctuation between solar cells. Furthermore, as a result of further detailed examination, they have found that the voltage fluctuation between solar cells can be suppressed when the porous layer contains at least one of insulating material, and particularly, a solid material is used as a hole transport material. The invention has been completed based on this knowledge.

That is, the object is solved by the following means.

<1> A photoelectric conversion element including a first electrode which has a porous layer provided on a conductive support and a photosensitive layer having a light absorber on a surface of the porous layer, a second electrode which is opposed to the first electrode, and a solid hole transport layer which is provided between the first electrode and the second electrode, in which the light absorber includes a compound having a perovskite crystal structure having a cation of a group I element of the periodic table or a cation of a cationic organic group A, a cation of a metal atom M other than the group I elements of the periodic table, and an anion of an anionic atom X, and the porous layer contains at least one of insulating material.

<2> The photoelectric conversion element according to <1>, in which the porous layer contains at least one of porous material different from the insulating material.

<3> The photoelectric conversion element according to <1> or <2>, in which the insulating material is contained in the porous layer in an amount of 5 mass % to 95 mass %.

<4> The photoelectric conversion element according to any one of <1> to <3>, in which the insulating material is contained in the porous layer in an amount of 5 mass % to 50 mass %.

<5> The photoelectric conversion element according to any one of <2> to <4>, in which the porous layer contains the insulating material and the porous material different from the insulating material, and on a surface of one of the insulating material or the porous material, the other of the insulating material or the porous material is disposed.

<6> The photoelectric conversion element according to any one of <2> to <5>, in which the porous layer has the insulating material on a surface of the porous material different from the insulating material.

<7> The photoelectric conversion element according to <5> or <6>, wherein at least a part of the surface of the one of the insulating material or the porous material is covered with the other of the insulating material or the porous material.

<8> The photoelectric conversion element according to any one of <2> to <7>, in which one of the insulating material and one of the porous material different from the insulating material are contained.

<9> The photoelectric conversion element according to any one of <1> to <8>, in which the insulating material is selected from the group consisting of oxides of zirconium, aluminum, and silicon.

<10> The photoelectric conversion element according to any one of <2> to <9>, in which the porous material different from the insulating material is selected from the group consisting of oxides of titanium, zinc, tin, tungsten, zirconium, aluminum, and silicon, and a carbon nano-tube.

<11> The photoelectric conversion element according to any one of <2> to <10>, in which the porous material different from the insulating material has a conduction band with an energy level that is the same as or lower than the lowest unoccupied molecular orbital of the perovskite light absorber.

<12> The photoelectric conversion element according to any one of <2> to <11>, in which the insulating material is an oxide of zirconium or aluminum, and the porous material different from the insulating material is an oxide of titanium, zinc, tin, or tungsten.

<13> The photoelectric conversion element according to any one of <1> to <12>, in which the compound having a perovskite crystal structure is a compound represented by the following Formula (I).

AₐMₘXₓ Formula (I):

In the formula, A represents a group I element of the periodic table or a cationic organic group, M represents a metal atom other than the group I elements of the periodic table, X represents an anionic atom, a represents 1 or 2, m represents 1, and a, m, and x satisfy a+2 m=x.

<14> The photoelectric conversion element according to any one of <1> to <13>, in which the compound having a perovskite crystal structure includes a compound represented by the following Formula (I-1).

AMX₃ Formula (I-1):

In the formula, A represents a group I element of the periodic table or a cationic organic group, M represents a metal atom other than the group I elements of the periodic table, and X represents an anionic atom.

<15> The photoelectric conversion element according to any one of <1> to <14>, in which the compound having a perovskite crystal structure includes a compound represented by the following Formula (I-2).

A₂MX₄ Formula (I-2):

In the formula, A represents a group I element of the periodic table or a cationic organic group, M represents a metal atom other than the group I elements of the periodic table, and X represents an anionic atom.

<16> The photoelectric conversion element according to any one of <1> to <15>, in which A is a cationic organic group represented by the following Formula (1).

R^{1a}—NH₃ Formula (1):

In the formula, R^{1a} represents a substituent.

<17> The photoelectric conversion element according to <16>, in which R^{1a} is an alkyl group, a cycloalkyl group, an alkenyl group, an alkynyl group, an aryl group, a heteroaryl group, or a group represented by the following Formula (2).

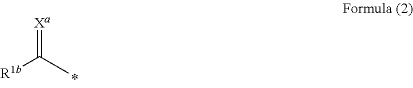

In the formula, X^{a} represents NR^{1c}, an oxygen atom, or a sulfur atom, each of R^{1b} and R^{1c} independently represents a hydrogen atom or a substituent, and * represents a bonding position with the N atom of Formula (1).

<18> The photoelectric conversion element according to any one of <1> to <17>, in which X is a halogen atom.

<19> The photoelectric conversion element according to any one of <1> to <18>, in which M is a Pb atom or a Sn atom.

<20> A solar cell including the photoelectric conversion element according to any one of <1> to <19>.

In the invention, the “porous layer” is a layer functioning as a foundation to carry the photosensitive layer on the surface thereof. This porous layer is referred to as a fine particle layer with pores, which is formed by accumulating a porous material.

The “porous material” is a material which can form the porous layer regardless of electrical properties. Accordingly, in the invention, the porous material includes a conductor (conductive material), a semiconductor (semiconductive material), and an insulator (insulating material).

The “insulating material” included in the porous material is a material which can form the porous layer, and is a material having a conduction band (CB) with a higher (shallower) energy level than the lowest unoccupied molecular orbital (LUMO) of a perovskite light absorber. That is, the insulating material is a porous material having insulating properties (insulating porous material) in the relationship with the perovskite light absorber to be used in combination.

The “porous material” includes an insulating material, but is preferably a material having a bottom of the conduction band with an energy level that is the same as or lower (deeper) than the lowest unoccupied molecular orbital of the perovskite light absorber. That is, the “porous material” is preferably a material which can form the porous layer, and is preferably a conductive material or a semiconductive material (hereinafter, the combination of both may be referred to as semiconductive porous material) in the relationship with the perovskite light absorber to be used in combination.

Accordingly, in the invention, the “porous material different from the insulating material” has no particular limits in regard to electrical properties, and a material which is not the same insulating material can be exemplified. For example, it means an insulating material different from the “at least one of insulating material”, and also means a semiconductive porous material, and a semiconductive porous material is preferred.

In this description, the respective formulae, particularly, Formulae (1), (2), and (An may be partially represented as rational formulae in order to understand the chemical structure of the compound having a perovskite crystal structure. With this, partial structures are called groups, substituents, atoms, or the like in the respective formulae, but in this description, these mean groups represented by the above formulae, or element groups or elements constituting the (substituent) groups.

In this description, regarding representation of compounds (including complex and dye), the compounds are used to mean not only the compounds themselves, but also salts and ions thereof. These also include compounds having a structure partially modified within the scope of causing target effects. Regarding compounds having no specification about substitution or unsubstitution, these mean compounds including compounds having an arbitrary substituent within the scope of causing desired effects. This is also applied to the cases of the substituent and the linking group (hereinafter, referred to as substituent and the like).

In this description, when there are more than one substituent and the like indicated by a specific reference, or when a plurality of substituents and the like are simultaneously specified, the respective substituents and the like may be the same as or different from each other unless otherwise mentioned. This is also applied to the case of the specification of the number of substituents and the like. In addition, when a plurality of sub stituents and the like are close to each other (particularly, adjacent to each other), these may be connected to each other and form a ring unless otherwise mentioned. In addition, rings such as an aliphatic ring, an aromatic ring, and a hetero ring may be condensed and form a condensed ring.

In this description, the numerical value range expressed using “to” means a range including the numerical values described before and after “to” as a lower limit value and an upper limit value.

According to the invention, it is possible to provide a photoelectric conversion element which exhibits stable cell performance with less voltage fluctuation, and a solar cell including the photoelectric conversion element.

### BRIEF DESCRIPTION OF THE DRAWINGS

FIG. 1 is a cross-sectional view schematically showing a preferred aspect of a photoelectric conversion element of the invention.

FIG. 2 is a cross-sectional view schematically showing a preferred aspect in which the photoelectric conversion element of the invention has a thick photosensitive layer.

FIG. 3A, FIG. 3B, and FIG. 3C illustrate a crystal structure of a perovskite compound.

### DESCRIPTION OF THE PREFERRED EMBODIMENTS

<<Photoelectric Conversion Element>>

A photoelectric conversion element of the invention has a first electrode having a conductive support, a porous layer, and a photosensitive layer, a second electrode opposed to the first electrode, and a solid hole transport layer provided between the first electrode and the second electrode. This photosensitive layer has a light absorber on a surface of the porous layer.

In the invention, the porous layer is preferably a fine particle layer formed by accumulating a porous material including at least one of insulating material, and the type of the porous material, the combination, the accumulation state, and the like are not particularly limited.

The porous material may include one of insulating material, but in the invention, preferably includes two or more types of porous materials containing at least one of insulating material. As the type and combination of such a porous material, a combination of “at least one of insulating material and at least one of porous material different from the insulating material” can be exemplified. For example, both of an aspect in which two or more types of insulating materials are combined and an aspect in which at least one of insulating material and at least one of semiconductive porous material are combined are included. In the invention, a combination of at least one of insulating material and at least one of semiconductive porous material is preferred, and examples thereof include a combination of at least one of preferred insulating material to be described later and at least one of preferred semiconductive porous material to be described later. In addition, one of insulating material and one of porous material different from the insulating material are preferably included.

The accumulation state of the porous material is not particularly limited, and as will be described later, the porous material is preferably accumulated such that the porous layer has pores. In the invention, the accumulated porous material may be in a state of being packed together and being capable of forming a porous structure. The “state of being . . . capable of forming a porous structure” includes a state in which the porous material is compressed or charged and a state in which the porous material is firmly adhered, fused, or sintered.

In the invention, the porous material including at least one of insulating material may be accumulated in any aspect. Examples of the “accumulation state” of the porous material include an aspect in which a plurality of types of porous materials are accumulated in a mixed state, and an aspect in which in a state in which an insulating material and a porous material different from the insulating material are included, and on the surface of one (also referred to as first porous material) of the insulating material and the porous material, the other (that is, the other of the insulating material and the porous material; also referred to as second porous material) is disposed, the materials are accumulated. Here, the “state in which on the surface of the first porous material, the second porous material is disposed” is not particularly limited as long as one or more second porous materials are adhered to the surface of the first porous material. Preferred examples thereof include a state in which one or more second porous materials are dispersedly adhered on the surface of the first porous material, and a state in which one or more second porous materials cover (for example, are adhered in the form of a film) the surface of the first porous material.

The second porous material may be adhered to or may cover a part or the whole of the surface of the first porous material. In addition, a first porous material having the second porous material on a part of the surface thereof and a first porous material having the second material on the entire surface thereof may be mixed with each other.

In the invention, the amount of the second porous material disposed on the surface of the first porous material, the coverage of the surface of the first porous material, and the like are not particularly limited. For example, the mass ratio of the second porous material (second porous material/(first porous material+second porous material)) is preferably 5 mass % to 95 mass %, and more preferably 5 mass % to 50 mass %.

In the invention, the second porous material is preferably an insulating material, and the first porous material is preferably a porous material different from the insulating material which is the second porous material, and particularly preferably a semiconductive porous material.

In the invention, the light absorber may contain at least one or two or more types of compounds having a perovskite crystal structure to be described later.

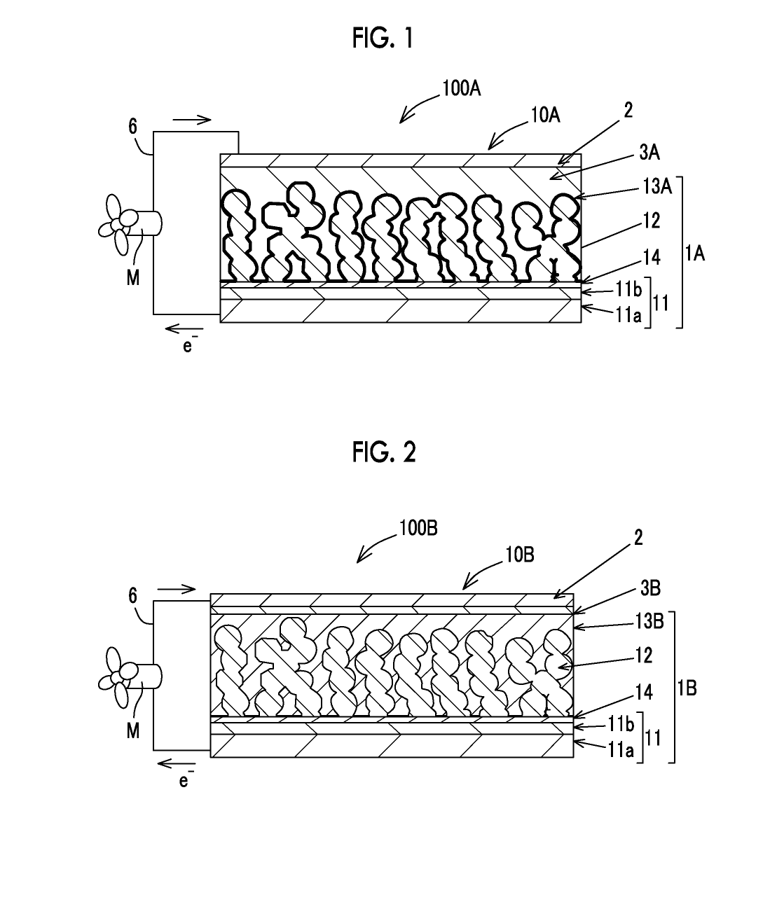

In the invention, the photosensitive layer can be formed in various forms on the surface of the porous layer according to the shape of the porous layer, the amount of the light absorber to be provided, and the like. Accordingly, in the invention, the photosensitive layer is provided in any aspect as long as it is provided on the surface of the porous layer. Examples of the aspect in which the photosensitive layer is formed on the surface of the porous layer include an aspect in which the photosensitive layer is provided in the form of a thin film or the like on the surface of the porous layer (see FIG. 1), and an aspect in which the photosensitive layer is provided to have a large thickness on the surface of the porous layer (see FIG. 2). The photosensitive layer may be provided in the form of a line or dispersedly, and preferably in the form of a film.

The configurations of the photoelectric conversion element of the invention, other than the configurations specified in the invention, are not particularly limited, and known configurations related to the photoelectric conversion element and the solar cell can be employed. The respective layers constituting the photoelectric conversion element of the invention are designed according to the purpose, and may be formed into either a single layer or a multi-layer.

For example, in the invention, the photosensitive layer may be a single layer or a lamination layer of two or more layers. When the photosensitive layer is a lamination layer, layers formed of different light absorbers may be laminated, or an intermediate layer containing a hole transport material may be laminated between the photosensitive layers.

Hereinafter, preferred aspects of the photoelectric conversion element of the invention will be described.

In FIGS. 1 and 2, the same references represent the same constituent elements (members).

FIGS. 1 and 2 show the size of fine particles which form the porous layer in an emphasized manner. These fine particles are preferably stuck (accumulated or firmly adhered) in a horizontal direction and in a vertical direction relative to the conductive support to form a porous structure.

In this description, when simply using the expression “photoelectric conversion element 10”, it means photoelectric conversion elements 10A and 10B unless otherwise mentioned. This is also applied to the cases of “system 100”, “first electrode 1”, “photosensitive layer 13”, and “hole transport layer 3”.

As a preferred aspect of the photoelectric conversion element of the invention, a photoelectric conversion element 10A shown in FIG. 1 can be exemplified. A system 100A shown in FIG. 1 is a system in which the photoelectric conversion element 10A is applied for use in a cell to make operation means M (for example, electric motor) work by an external circuit 6.

This photoelectric conversion element 10A has a first electrode 1A, a second electrode 2, and a solid hole transport layer 3A. The first electrode 1A has a conductive support 11 formed of a support 11a and a transparent electrode 11b, a porous layer 12, and a photosensitive layer 13A. It is preferable that a blocking layer 14 is provided on the transparent electrode 11b and a porous layer 12 is formed on the blocking layer 14.

A photoelectric conversion element 10B shown in FIG. 2 schematically shows a preferred aspect in which the photosensitive layer 13A of the photoelectric conversion element 10A shown in FIG. 1 is provided to have a large thickness. In this photoelectric conversion element 10B, a hole transport layer 3B is provided to have a small thickness. The photoelectric conversion element 10B is different from the photoelectric conversion element 10A shown in FIG. 1 in terms of the photosensitive layer 13B and the solid hole transport layer 3B, but except for this, the photoelectric conversion element 10B has the same configuration as the photoelectric conversion element 10A.

In the invention, the system 100 applying the photoelectric conversion element 10 functions as a solar cell as follows.

That is, in the photoelectric conversion element 10, the light transmitted through the conductive support 11 or the second electrode 2 and entering the photosensitive layer 13 excites the light absorber. The excited light absorber has high-energy electrons, and the electrons reach the conductive support 11 from the photosensitive layer 13. At this time, the light absorber emitting the high-energy electrons becomes an oxidant. The electrons reaching the conductive support 11 return to the photosensitive layer 13 through the second electrode 2 and the hole transport layer 3 while working in the external circuit 6. The light absorber is reduced by the electrons returning to the photosensitive layer 13. The system 100 functions as a solar cell by repeating the excitation of the light absorber and the transfer of the electrons.

The flow of the electrons from the photosensitive layer 13 to the conductive support 11 varies with the type and the conductive properties of the porous layer 12, and the like. The flow of the electrons from the photosensitive layer 13 to the conductive support 11 will be described later.

The photoelectric conversion element and the solar cell of the invention are not limited to the preferred aspects, and the configurations and the like of the respective aspects can be appropriately combined between the aspects without departing from the gist of the invention.

In the invention, except for the porous layer 12, the perovskite compound as a light absorber (sensitizer), and the solid hole transport layer 3, the materials and the members used in the photoelectric conversion element or the solar cell can be prepared through usual methods. For example, KR10-1172374B and J. Phys. Chem. Lett., 2013, 4, 1532-1536 can be referred to regarding a photoelectric conversion element or a solar cell using a perovskite compound. In addition, for example, JP2001-291534A, U.S. Pat. No. 4,927,721A, U.S. Pat. No. 4,684,537A, U.S. Pat. No. 5,084,365A, U.S. Pat. No. 5,350,644A, U.S. Pat. No. 5,463,057A, U.S. Pat. No. 5,525,440A, JP1995-249790A (JP-H7-249790A), JP2004-220974A, and JP2008-135197A can be referred to regarding a dye-sensitized solar cell.

Hereinafter, preferred aspects of main members and compounds of the photoelectric conversion element and the solar cell of the invention will be described.

<First Electrode 1>

The first electrode 1 has the conductive support 11, the porous layer 12, and the photosensitive layer 13, and functions as a working electrode in the photoelectric conversion element 10.

The first electrode 1 preferably has the blocking layer 14.

—Conductive Support 11—

The conductive support 11 is not particularly limited as long as it has conductive properties and can support the porous layer 12, the photosensitive layer 13, and the like. The conductive support is preferably a conductive support made of a conductive material such as a metal, or a conductive support 11 having a glass or plastic support 11a and a conductive film as a transparent electrode 11b formed on a surface of the support 11a.

Among these, a conductive support 11 in which a transparent electrode 11b is formed by coating a surface of a glass or plastic support 11a with a conductive metal oxide as shown in FIGS. 1 and 2 is more preferred. Examples of the plastic support 11a include transparent polymer films described in paragraph 0153 of JP2001-291534A. As the material which forms the support 11a, ceramics (JP2005-135902A) or a conductive resin (JP2001-160425A) can be used other than glass and plastic. As the metal oxide, a tin oxide (TO) is preferred, and an indium-tin oxide (tin-doped indium oxide; ITO) and a fluorine-doped tin oxide such as a tin oxide doped with fluorine (FTO) are particularly preferred. At this time, the amount of the metal oxide applied is preferably 0.1 g to 100 g per surface area of 1 m² of the support 11a. When using the conductive support 11, light preferably enters from the side of the support 11a.

The conductive support 11 is preferably substantially transparent. In the invention, the expression “substantially transparent” means that the transmittance of light (wavelength: 300 nm to 1200 nm) is 10% or greater, and the transmittance is preferably 50% or greater, and particularly preferably 80% or greater.

The thicknesses of the support 11a and the conductive support 11 are not particularly limited and are set to appropriate thicknesses. For example, the thicknesses are preferably 0.01 μm to 10 mm, more preferably 0.1 μm to 5 mm, and particularly preferably 0.3 μm to 4 mm.

When providing the transparent electrode 11b, the thickness of the transparent electrode 11b is not particularly limited. For example, the thickness is preferably 0.01 μm to more preferably 0.03 μm to 25 μm, and particularly preferably 0.05 μm to 20 μm.

The surface of the conductive support 11 or the support 11a may have a light management function. For example, an anti-reflection film described in JP2003-123859A, obtained by alternately laminating a high-refraction film and an oxide film having a low refractive index, may be provided on the surface of the conductive support 11 or the support 11a, or a light guide function described in JP2002-260746A may be imparted thereto.

—Blocking Layer 14—

In the invention, the blocking layer 14 is preferably provided on a surface of the transparent electrode 11b, that is, between the conductive support 11 and the porous layer 12 or the hole transport layer 3.

In the photoelectric conversion element and the solar cell, when the solid hole transport layer 3 and the transparent electrode 11b are brought into direct contact with each other, a reverse current is generated. The blocking layer 14 functions to prevent the reverse current. The blocking layer 14 is also called a short circuit prevention layer.

The material which forms the blocking layer 14 is not particularly limited as long as it is a material capable of serving the above-described function. However, the material is preferably a visible light transmissive substance having insulating properties with respect to the conductive support 11 (transparent electrode 11b). Specifically, the “substance having insulating properties with respect to the conductive support 11 (transparent electrode 11b)” indicates a compound (n-type semiconductor compound) having a conduction band energy level that is not lower than that of the material which forms the conductive support 11 (a metal oxide which forms the transparent electrode 11b) and is lower than those of the material which forms the porous layer 12 and the light absorber in a ground state.

Examples of the material which forms the blocking layer 14 include silicon oxide, magnesium oxide, aluminum oxide, calcium carbonate, polyvinyl alcohol, and polyurethane. In addition, the material may be a material which is usually used as a photoelectric conversion material, and examples thereof include titanium oxide, tin oxide, niobium oxide, and tungsten oxide. Among these, titanium oxide, tin oxide, magnesium oxide, aluminum oxide, and the like are preferred.

The thickness of the blocking layer 14 is preferably 0.001 μm to 10 μm, more preferably 0.005 μm to 1 μm, and particularly preferably 0.01 μm to 0.1 μm.

—Porous Layer 12—

In the invention, the porous layer 12 is formed on the transparent electrode 11b. When the blocking layer 14 is provided, the porous layer 12 is formed on the blocking layer 14.

As described above, the porous layer 12 is a layer including at least one of insulating material, and is preferably a fine particle layer. The porous layer 12 is preferably a fine particle layer formed by accumulating two or more types of insulating materials, or a fine particle layer formed by accumulating at least one of insulating material and at least one of porous material (preferably semiconductive porous material) different from the insulating material. In the invention, the porous layer 12 is more preferably a fine particle layer formed by accumulating at least one of insulating material and at least one of porous material.

In this case, regarding the porous layer 12, an insulating material and a porous material different from the insulating material may be accumulated in a mixed state, but from the viewpoint of achieving an effect of suppressing the voltage fluctuation, it is more preferable that an insulating material and a porous material different from the insulating material are included, and fine particles having, on the surfaces of fine particles of one (first porous material) of the insulating material and the porous material, fine particles of the other (second porous material) are accumulated. Among these, it is particularly preferable that regarding the porous layer 12, fine particles having the insulating material as the second porous material on the surface of the porous material (preferably semiconductive porous material) as the first porous material are accumulated. The state of “having the second porous material on the first porous material” is as described above.

Here, the flow of the electrons from the photosensitive layer 13 to the conductive support 11 will be described.

When the porous layer 12 is formed of an insulating material, excited electrons transfer between perovskite light absorbers provided on the surface of the porous layer 12 and reach the conductive support 11. In this case, only one electron conduction path exists, and the electrons are not injected into the porous layer 12. Therefore, no reverse electron transfer path from the porous material forming the porous layer 12 to the hole transport material is generated. Accordingly, the voltage fluctuation between solar cells is thought to be suppressed to some extent.

When the porous layer 12 is formed only of a semiconductive porous material, there are two paths where excited electrons finally reach the conductive support 11, including a path where the electrons transfer between the perovskite light absorbers provided on the surface of the porous layer 12 and a path where the electrons transfer in the semiconductive porous material and across the space between the semiconductive porous materials.

When the porous layer 12 is a fine particle layer formed by accumulating at least one of insulating material and at least one of porous material (semiconductive porous material) different from the insulating material, there are two paths where excited electrons finally reach the conductive support 11, including a path where the electrons transfer between the perovskite light absorbers and a path where the electrons transfer in the semiconductive porous material and across the space between the semiconductive porous materials.

However, when the porous layer 12 contains at least one of insulating material, the ratio of the path where the electrons pass through the inside of the semiconductive porous material is relatively smaller than in the case in which the porous layer 12 is formed only of a semiconductive porous material, and together with this, the voltage fluctuation by reverse electron transfer is thought to also be suppressed to some extent.

In the invention, when the porous layer 12 contains at least one of insulating material, the voltage fluctuation between solar cells can be suppressed. The reason for this is not yet clear, but is estimated as follows. That is, when the porous layer 12 contains a semiconductive porous material as a porous material, reverse electron transfer occurs from the semiconductive porous material to the hole transport layer. However, in the invention, this reverse electron transfer is estimated to be suppressed as described above due to the insulating material contained in the porous layer.

The effect of suppressing the voltage fluctuation between solar cells is significant when the hole transport layer is in a solid state. The reason for this is also not clear, but is estimated as follows. That is, in order to cause reverse electron transfer in a solution type hole transport layer, an electron-receiving substance is required to closely approach the porous material through diffusion in the hole transport layer. In contrast, in a solid type hole transport layer, there is a part in which the porous material and the hole transport material are always in contact with each other. Accordingly, the influence of the voltage fluctuation in the solid type is relatively larger than in the solution type in which the electron-receiving substance is required to approach the porous material. Therefore, the effect of suppressing the voltage fluctuation by the estimated mechanism that suppresses the influence of the reverse electron transfer is thought to be increased in the solid type.

The content ratio of the insulating material in the porous layer 12 is preferably 5 mass % to 95 mass %, and more preferably 5 mass % to 50 mass % in the total solid content of the porous layer 12 regardless of the aspect of the porous layer 12 and the like from the viewpoint of suppressing the voltage fluctuation. That is, the content of the semiconductive porous material as the porous material is preferably 5 mass % to 95 mass %, and more preferably 50 mass % to 95 mass %.

When the porous layer 12 is a fine particle layer with pores, the amount of the light absorber carried (adsorbed) can be increased. In the solar cell, in order to increase the light absorption efficiency, the surface area of at least a part which receives light such as solar light is preferably increased, and the entire surface area of the porous layer 12 is more preferably increased.

The surface areas of the respective fine particles constituting the porous layer 12 are preferably increased to increase the surface area of the porous layer 12. In the invention, in a state in which the conductive support 11 or the like is coated with fine particles which form the porous layer 12, the surface area of the fine particles is preferably 10 or more times, and more preferably 100 or more times the projected area. The upper limit thereof is not particularly limited, but generally about 5000 times.

The thickness of the porous layer 12 is not particularly limited, but usually within a range of 0.1 μm to 100 μm. When the photoelectric conversion element is used as a solar cell, the thickness is preferably 0.1 μm to 50 μm, and more preferably 0.3 μm to 30 μm.

The thickness of the porous layer 12 is specified by an average distance from the surface of the underlying layer on which the porous layer 12 is formed to the surface of the porous layer 12 along a linear direction intersecting at an angle of 90° relative to the surface of the conductive support 11 in a cross-section of the photoelectric conversion element 10. Here, the “surface of the underlying layer on which the porous layer 12 is formed” means an interface between the conductive support 11 and the porous layer 12. When other layers such as the blocking layer 14 are formed between the conductive support 11 and the porous layer 12, the above expression, “surface of the underlying layer on which the porous layer 12 is formed”, means an interface between the above other layers and the porous layer 12. In addition, the “surface of the porous layer 12” is, on a virtual straight line intersecting at an angle of 90° relative to the surface of the conductive support 11, a point of the porous layer 12 positioned closest to the side of the second electrode 2 from the conductive support 11 (intersection point between the virtual straight line and the outline of the porous layer 12). The “average distance” means an average of ten farthest distances, each of which is obtained by obtaining a farthest distance from the surface of the underlying layer to the surface of the porous layer 12 for each of ten parts obtained by equally dividing a specific observation region in a cross-section of the photoelectric conversion element 10 into ten along a direction (horizontal direction in FIGS. 1 and 2) horizontal to (parallel to) the surface of the conductive support 11. The thickness of the porous layer 12 can be measured by observing the cross-section of the photoelectric conversion element 10 with a scanning electron microscope (SEM).

Unless otherwise mentioned, thicknesses of other layers such as the blocking layer 14 can also be measured in the same manner.

The porous layer 12 containing at least one of insulating material is formed of a porous material containing at least one of insulating material. Here, the “porous material” and the “insulating material” are as described above.

As the porous material, a chalcogenide (for example, oxide, sulfide, selenide, and the like) of a metal, a compound having a perovskite crystal structure (except for light absorber to be described later), a silicon oxide (for example, silicon dioxide and zeolite), or a carbon nano-tube (also referred to as CNT, including carbon nano-wire, carbon nano-rod, and the like) can be used.

The chalcogenide of a metal is not particularly limited, and preferred examples thereof include an oxide of titanium, tin, zinc, tungsten, zirconium, hafnium, strontium, indium, cerium, yttrium, lanthanum, vanadium, niobium, aluminum, or tantalum, cadmium sulfide, and cadmium selenide. Examples of the crystal structure of the chalcogenide of a metal include an anatase type, a brookite type, and a rutile type, and an anatase type and a brookite type are preferred.

The compound having a perovskite crystal structure is not particularly limited, and examples thereof include a transition metal oxide. Examples thereof include strontium titanate, calcium titanate, barium titanate, lead titanate, barium zirconate, barium stannate, lead zirconate, strontium zirconate, strontium tantalate, potassium niobate, bismuth ferrate, strontium barium titanate, barium lanthanum titanate, calcium titanate, sodium titanate, and bismuth titanate. Among these, strontium titanate, calcium titanate, and the like are preferred.

The carbon nano-tube has a shape in which a carbon film (graphene sheet) is rounded into a cylindrical shape. The carbon nano-tube is classified into a single-layer carbon nano-tube (SWCNT) in which one graphene sheet is wound into a cylindrical shape, a double-layer carbon nano-tube (DWCNT) in which two graphene sheets are concentrically wound, and a multi-layer carbon nano-tube (MWCNT) in which a plurality of graphene sheets are concentrically wound. As the porous layer 12, any carbon nano-tube can be used with no particular limits.

In the invention, each of the insulating material and the semiconductive porous material is appropriately selected among, for example, the above-described porous materials in view of the relationship with the energy level of the lowest unoccupied molecular orbital of the perovskite light absorber. That is, when the energy level of the lowest unoccupied molecular orbital is compared to the energy level of the conduction band and the energy level of the conduction band is higher than the energy level of the lowest unoccupied molecular orbital, the insulating material is selected. When the energy level of the conduction band is not higher than the energy level of the lowest unoccupied molecular orbital, the semiconductive porous material is selected.

Here, a known value can be employed as the energy level of the conduction band of the porous material. For example, the value described in ACS Nano, 2011, 5(6), pp. 5158 to 5166, J. Am. Chem. Soc. 2003, 125, 475 can be used.

The energy level of the perovskite light absorber can be calculated based on the known method in Nanoscale Research Letters, 2012, 7:353.

In the invention, when the perovskite compound is used, the insulating material is preferably at least one selected from the group consisting of oxides of zirconium, aluminum, and silicon, and more preferably an oxide of zirconium or aluminum.

In the invention, the “porous material different from the insulating material” is not particularly limited as described above. Among the above-described materials, at least one selected from the group consisting of oxides of titanium, zinc, tin, tungsten, zirconium, aluminum, and silicon, and a carbon nano-tube is preferred.

As the porous material as the semiconductive porous material, an oxide of titanium, zinc, tin, or tungsten is preferred, and titanium oxide is more preferred.

The porous material is preferably used as fine particles, and more preferably as a dispersion dispersed in a dispersion medium. At this time, due to the above reason, the particle diameter of the porous material is preferably 0.001 μm to 1 μm as primary particles in terms of the average particle diameter using a diameter when the projected area is converted into a circle. When the porous layer 12 is formed using a dispersion of fine particles, the average particle diameter of the fine particles is preferably 0.01 μm to 100 μm as the average particle diameter of the dispersion. The average particle diameter can be measured using a scanning electron microscope or the like.

Regarding the material which forms the porous layer 12, a nano-tube, nano-wire, or nano-rod of a chalcogenide of a metal, a compound having a perovskite crystal structure, and an oxide of silicon may be used with fine particles of a chalcogenide of a metal, a compound having a perovskite crystal structure, an oxide of silicon, and a carbon nano-tube.

—Photosensitive Layer (Light Absorption Layer) 13μ

As shown in FIGS. 1 and 2, the photosensitive layer 13 is provided on the surface (when this surface has irregularities, interior surfaces thereof are included) of the porous layer 12. The surface of the porous layer 12 provided with the light absorber (having perovskite light absorber) may be either a surface of at least one of porous material, or a surface of a plurality of types of porous materials. For example, when the first porous material and the second porous material are used, the surface of the porous layer 12 provided with the light absorber may be either a surface of at least one of the first porous material and the second porous material, or a surface of both of the first porous material and the second porous material.

The aspect in which the photosensitive layer 13 is formed is as described above, and the photosensitive layer 13 is preferably provided on the surface of the porous layer 12 such that excited electrons flow to the conductive support 11. At this time, the photosensitive layer 13 may be provided on a part or the whole of the surface of the porous layer 12.

The thickness of the photosensitive layer 13 is appropriately set according to the aspect in which the photosensitive layer 13 is formed, and is not particularly limited. For example, the thickness of the photosensitive layer 13 is preferably 0.1 μm to 100 μm, more preferably 0.1 μm to 50 μm, and particularly preferably 0.3 μm to 30 μm in terms of the total thickness including the thickness of the porous layer 12.

Here, as shown in FIG. 1, when the photosensitive layer 13 has a thin film shape, a distance from an interface between the photosensitive layer 13 and the porous layer 12 to an interface between the photosensitive layer 13 and the hole transport layer 3 along a direction perpendicular to the surface of the porous layer 12 is set as the thickness of the photosensitive layer 13.

The photoelectric conversion element 10B shown in FIG. 2 has a photosensitive layer 13B having a larger thickness than the photosensitive layer 13A of the photoelectric conversion element 10A shown in FIG. 1. In this case, the perovskite compound as a light absorber may be a hole transport material as in the case of the above-described compound having a perovskite crystal structure as a material which forms the porous layer 12.

(Light Absorber)

The photosensitive layer 13 contains a perovskite compound as a light absorber.

In the invention, the light absorber may contain at least one of perovskite compound. In this case, one of perovskite compound may be used singly, or two or more types of perovskite compounds may be used in combination.

The perovskite compound has a group I element of the periodic table or a cationic organic group A, a metal atom M other than the group I elements of the periodic table, and an anionic atom X. The group I element of the periodic table or the cationic organic group A, the metal atom M, and the anionic atom X exist as constituent ions of a cation (for convenience, may be referred to as cation A), a metal cation (for convenience, may be referred to as cation M), and an anion (for convenience, may be referred to as anion X), respectively, in the perovskite crystal structure.

In the invention, the cationic organic group is an organic group having such properties as to be a cation in the perovskite crystal structure, and the anionic atom is an atom having such properties as to be an anion in the perovskite crystal structure.

The perovskite compound is not particularly limited as long as it is a compound which may have a perovskite crystal structure having, as constituent ions, a cation of a group I element of the periodic table or a cation of a cationic organic group A, a cation of a metal atom M other than the group I elements of the periodic table, and an anion of an anionic atom X.

In the perovskite compound used in the invention, the cation A is a cation of a group I element of the periodic table or an organic cation consisting of a cationic organic group A. The cation A is preferably an organic cation.

The cation of a group I element of the periodic table is not particularly limited, and examples thereof include cations (Li⁺, Na⁺, K⁺, Cs+) of elements of lithium (Li), sodium (Na), potassium (K), and cesium (Cs). A cation (Cs⁺) of cesium is particularly preferred.

The organic cation is preferably an organic ammonium cation, and preferably an organic ammonium cation represented by the following Formula (1).

R^{1a}—NH₃ Formula (1):

In the formula, R^{1a} represents a substituent. R^{1a} is not particularly limited as long as it is an organic group. Preferred examples thereof include an alkyl group, a cycloalkyl group, an alkenyl group, an alkynyl group, an aryl group, a heteroaryl group, and a group represented by the following Formula (2). Among these, an alkyl group and a group represented by the following Formula (2) are more preferred.

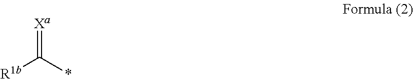

In the formula, X^{a} represents NR^{1c}, an oxygen atom, or a sulfur atom. Each of R^{1b} and R^{1c} independently represents a hydrogen atom or a substituent. * represents a bonding position with the N atom of Formula (1).

In the invention, the organic cation of the cationic organic group A is preferably an organic ammonium cation consisting of an ammonium cationic organic group A produced by bonding R^{1a} and NH₃ in Formula (1). When this organic ammonium cation has a resonance structure, the organic cation includes a cation having a resonance structure in addition to the organic ammonium cation. For example, when X^{a} is NH (R^{1c} is a hydrogen atom) in the group represented by Formula (2), the organic cation also includes, in addition to the organic ammonium cation of the ammonium cationic organic group produced by bonding the group represented by Formula (2) and NH₃, an organic amidinium cation which is one of resonance structures of the organic ammonium cation. A cation represented by the following Formula (A′) can be exemplified as the organic amidinium cation consisting of the amidinium cationic organic group. In this description, the cation represented by the following Formula (A′) may be represented as “R^{1b}C (═NH)—NH₃” for convenience.

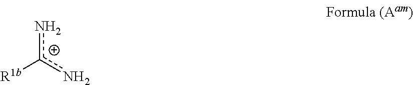

The alkyl group of the substituent R^{1a} is preferably an alkyl group having 1 to 18 carbon atoms, and examples thereof include methyl, ethyl, propyl, isopropyl, butyl, tert-butyl, pentyl, and hexyl.

The cycloalkyl group is preferably a cycloalkyl group having 3 to 8 carbon atoms, and examples thereof include cyclopropyl, cyclopentyl, and cyclohexyl.

The alkenyl group is preferably an alkenyl group having 2 to 18 carbon atoms, and examples thereof include vinyl, allyl, butenyl, and hexenyl.

The alkynyl group is preferably an alkynyl group having 2 to 18 carbon atoms, and examples thereof include ethynyl, butynyl, and hexynyl.

The aryl group is preferably an aryl group having 6 to 14 carbon atoms, and examples thereof include phenyl.

The heteroaryl group includes a group formed only of an aromatic hetero ring and a group formed of a condensed hetero ring obtained by condensing an aromatic hetero ring with other rings such as an aromatic ring, an aliphatic ring, and a hetero ring.

A nitrogen atom, an oxygen atom, and a sulfur atom are preferred as a ring-constituent hetero atom constituting the aromatic hetero ring. The number of membered rings of the aromatic hetero ring is preferably 5 or 6.

Examples of the five-membered aromatic hetero ring and the condensed hetero ring including a five-membered aromatic hetero ring include ring groups of a pyrrole ring, an imidazole ring, a pyrazole ring, an oxazole ring, a thiazole ring, a triazole ring, a furan ring, a thiophene ring, a benzoimidazole ring, a benzoxazole ring, a benzothiazole ring, an indoline ring, and an indazole ring. Examples of the six-membered aromatic hetero ring and the condensed hetero ring including a six-membered aromatic hetero ring include ring groups of a pyridine ring, a pyrimidine ring, a pyrazine ring, a triazine ring, a quinoline ring, and a quinazoline ring.

In the group represented by Formula (2), X^{a} represents NR^{1c}, an oxygen atom, or a sulfur atom, and is preferably NR^{1c}. Here, R^{1c} is preferably a hydrogen atom, an alkyl group, a cycloalkyl group, an alkenyl group, an alkynyl group, an aryl group, or a heteroaryl group, and more preferably a hydrogen atom.

R^{1b} represents a hydrogen atom or a substituent, and is preferably a hydrogen atom. Examples of the substituent which can be taken by R^{1b} include a hydrogen atom, an alkyl group, a cycloalkyl group, an alkenyl group, an alkynyl group, an aryl group, and a heteroaryl group.

The alkyl group, the cycloalkyl group, the alkenyl group, the alkynyl group, the aryl group, and the heteroaryl group, which can be taken by R^{1b} and R^{1c}, are synonymous with the groups of R^{1a}, and preferred groups are also the same as those of R^{1a}.

Examples of the group represented by Formula (2) include formimidoyl (HC(═NH)—), acetoimidoyl (CH₃C(═NH)—), and propionimidoyl (CH₃CH₂C(═NH)—). Among these, formimidoyl is preferred.

Any of the alkyl group, the cycloalkyl group, the alkenyl group, the alkynyl group, the aryl group, the heteroaryl group, and the group represented by Formula (2), all of which can be taken by R^{1a}, may have a substituent. The substituent that R^{1a} may have is not particularly limited, but examples thereof include an alkyl group, a cycloalkyl group, an alkenyl group, an alkynyl group, an aryl group, a heterocyclic group, an alkoxyl group, an alkylthio group, an amino group, an alkylamino group, an arylamino group, an acyl group, an alkoxycarbonyl group, an aryloxycarbonyl group, an acylamino group, a sulfonamide group, a carbamoyl group, a sulfamoyl group, a halogen atom, a cyano group, a hydroxy group, and a carboxy group. Each substituent that R^{1a} may have may be further substituted with a substituent.

In the perovskite compound used in the invention, the metal cation M is not particularly limited as long as it is a cation of a metal atom M other than the group I elements of the periodic table, and is a cation of a metal atom which may have the perovskite crystal structure. Examples of such a metal atom include metal atoms of calcium (Ca), strontium (Sr), cadmium (Cd), copper (Cu), nickel (Ni), manganese (Mn), iron (Fe), cobalt (Co), palladium (Pd), germanium (Ge), tin (Sn), lead (Pb), ytterbium (Yb), europium (Eu), and indium (In). Among these, a Pb atom or a Sn atom is particularly preferred as the metal atom which forms the metal cation. The metal atoms may be one of metal atoms or two or more of metal atoms. When the metal atoms are two or more of metal atoms, two of a Pb atom and a Sn atom are preferred. At this time, the ratio of the metal atoms is not particularly limited.

In the perovskite compound used in the invention, the anion X represents an anion of the anionic atom X. The anion is preferably an anion of a halogen atom. Examples of the halogen atom include a fluorine atom, a chlorine atom, a bromine atom, and an iodine atom. The anions X may be anions of one of anionic atom or anions of two or more types of anionic atoms. When the anions X are anions of two or more types of anionic atoms, anions of two types of halogen atoms, particularly, an anion of a bromine atom and an anion of an iodine atom are preferred. At this time, the ratio of the anions of the anionic atoms is not particularly limited.

The perovskite compound used in the invention has a perovskite crystal structure having the above-described constituent ions, and a perovskite compound represented by the following Formula (I) is preferred.

AₐMₘXₓ Formula (I):

In the formula, A represents a group I element of the periodic table or a cationic organic group.

M represents a metal atom other than the group I elements of the periodic table. X represents an anionic atom.

a represents 1 or 2, m represents 1, and a, m, and x satisfy a+2 m=x. That is, when a is 1, x is 3, and when a is 2, x is 4.

In Formula (I), the group I element of the periodic table or the cationic organic group A forms the cation A of the perovskite crystal structure. Accordingly, the group I element of the periodic table and the cationic organic group A are not particularly limited as long as the element or the group can form the cation A and can constitute the perovskite crystal structure. The group I element of the periodic table or the cationic organic group A is synonymous with the group I element of the periodic table or the cationic organic group in the description of the cation A, and preferred examples thereof are also the same as those of the group I element of the periodic table or the cationic organic group in the description of the cation A.

The metal atom M is a metal atom which forms the metal cation M of the perovskite crystal structure. Accordingly, the metal atom M is not particularly limited as long as it is an atom other than the group I elements of the periodic table, and is an atom which can form the metal cation M and can constitute the perovskite crystal structure. The metal atom M is synonymous with the metal atom in the description of the metal cation M, and preferred examples thereof are also the same as those of the metal atom in the description of the metal cation M.

The anionic atom X forms the anion X of the perovskite crystal structure. Accordingly, the anionic atom X is not particularly limited as long as it is an atom which can form the anion X and can constitute the perovskite crystal structure. The anionic atom X is synonymous with the anionic atom in the description of the anion X, and preferred examples thereof are also the same as those of the anionic atom in the description of the anion X.

The perovskite compound represented by Formula (I) is a perovskite compound represented by the following Formula (I-1) when a is 1, and the perovskite compound represented by Formula (I) is a perovskite compound represented by the following Formula (I-2) when a is 2.

AMX₃ Formula (I-1):

A₂MX₄ Formula (I-2):

In Formulae (I-1) and (I-2), A represents a group I element of the periodic table or a cationic organic group, and is synonymous with A of Formula (I). Preferred examples thereof are also the same as those of A.

M represents a metal atom other than the group I elements of the periodic table, and is synonymous with M of Formula (I). Preferred examples thereof are also the same as those of M.

X represents an anionic atom, and is synonymous with X of Formula (I). Preferred examples thereof are also the same as those of X.

Here, the perovskite crystal structure will be described.

As described above, the perovskite crystal structure contains the cation A, the metal cation M, and the anion X as constituent ions.

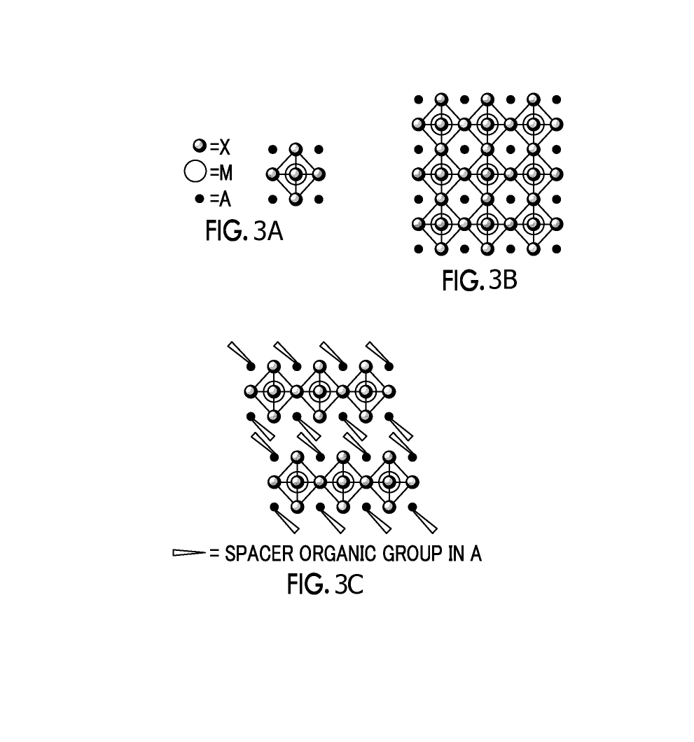

FIG. 3A is a diagram showing a fundamental unit lattice of the perovskite crystal structure, and FIG. 3B is a diagram showing a structure in which fundamental unit lattices are three-dimensionally continuous to each other in the perovskite crystal structure. FIG. 3C is a diagram showing a layered structure in which an inorganic layer and an organic layer are alternately laminated in the perovskite crystal structure.

The perovskite compound represented by Formula (I-1) has a cubic fundamental unit lattice in which, as shown in FIG. 3A, a cation A is disposed at each apex, a metal cation M is disposed at a body center, and an anion X is disposed at each face center of the cubic having the metal cation M as a center. In addition, the perovskite compound has a structure in which, as shown in FIG. 3B, one fundamental unit lattice shares a cation A and an anion X with each of other adjacent 26 fundamental unit lattices (surrounding the circumference) and fundamental unit lattices are three-dimensionally continuous to each other.

The perovskite compound represented by Formula (I-2) is the same as the perovskite compound represented by Formula (I-1) in terms of the fact that a MX₆ octahedron formed of a metal cation M and an anion X is provided, but is different therefrom in terms of the fundamental unit lattices and the arrangement form thereof. That is, the perovskite compound represented by Formula (I-2) has a layered structure in which, as shown in FIG. 3C, an inorganic layer formed by arranging MX₆ octahedrons two-dimensionally (in a plane shape) in a layer and an organic layer formed by inserting a cation A between inorganic layers are alternately laminated.

In such a layered structure, the fundamental unit lattices share cations A and anions X with other adjacent fundamental unit lattices in the surface of the same layer. The fundamental unit lattices do not share cations A and anions X in a different layer. This layered structure is a two-dimensional layered structure in which the inorganic layer is divided by the organic group of the cation A. As shown in FIG. 3C, the organic group in the cation A functions as a spacer organic group between the inorganic layers.

Regarding the perovskite compound having a layered structure, for example, New. J. Chem., 2008, 32, 1736 can be referred to.

The crystal structure of the perovskite compound is determined according to the cation A (group I element of the periodic table or cationic organic group A). For example, when the cation A is a cation of a group I element of the periodic table or an organic cation of a cationic organic group A having a substituent R^{1a} having one carbon atom and the like, the perovskite compound is represented by Formula (I-1) and is likely to have a cubic crystal structure. Examples of such a cation A include cations of CH₃—NH₃ and H—C(═NH)—NH₃ (when R^{1b} and R^{1c} are hydrogen atoms) among organic cations having a group represented by Formula (2).

When the cation A is a cation of a cationic organic group A having a substituent R^{1a} having two or more carbon atoms and the like, the perovskite compound is represented by Formula (I-2) and is likely to have a layered crystal structure. Examples of such a cation A include an organic cation of a cationic organic group A having an alkyl group, a cycloalkyl group, an alkenyl group, an alkynyl group, an aryl group, a heteroaryl group, or a group represented by Formula (2) (when R^{1b} and R^{1c} are substituents), which have been described as the substituent R^{1a} and have two or more carbon atoms.

The perovskite compound used in the invention may be either a compound represented by Formula (I-1) or a compound represented by Formula (I-2), or may be a mixture thereof. Accordingly, in the invention, at least one of perovskite compound may exist as the light absorber, and there is no need to strictly and clearly distinguish the compound according to the composition formula, molecular formula, crystal structure, and the like.

Hereinafter, specific examples of the perovskite compound used in the invention will be given, but the invention is not limited thereto. In the following description, the perovskite compound is classified into a compound represented by Formula (I-1) and a compound represented by Formula (I-2) in the description. However, even when a compound is exemplified as the compound represented by Formula (I-1), the exemplified compound may become the compound represented by Formula (I-2) or a mixture of the compound represented by Formula (I-1) and the compound represented by Formula (I-2) depending on synthesis conditions and the like. Similarly, even when a compound is exemplified as the compound represented by Formula (I-2), the exemplified compound may become the compound represented by Formula (I-1) or a mixture of the compound represented by Formula (I-1) and the compound represented by Formula (I-2).

Specific examples of the compound represented by Formula (I-1) include CH₃NH₃PbCl₃, CH₃NH₃PbBr₃, CH₃NH₃PbI₃, CH₃NH₃PbBrI₂, CH₃NH₃PbBr₂I, CH₃NH₃SnBr₃, CH₃NH₃SnI₃, and CH(═NH)NH₃PbI₃.

Specific examples of the compound represented by Formula (I-2) include (C₂H₅NH₃)₂PbI₄, (CH₂═CHNH₃)₂PbI₄, (CH≡CNH₃)₂PbI₄, (n-C₃H₇NH₃)₂PbI₄, (n-C₄H₉NH₃)₂PbI₄, (C₆H₅NH₃)₂PbI₄, (C₆H₃F₂NH₃)₂PbI₄, (C₆F₅NH₃)₂PbI₄, and (C₄H₃SNH₃)₂PbI₄.

Here, C₄H₃SNH₃ in (C₄H₃SNH₃)₂PbI₄ is aminothiophene.

The perovskite compound can be synthesized from MX₂ and AX. For example, the above-described J. Phys. Chem. Lett., 2013, 4, 1532-1536 can be exemplified. Akihiro Kojima, Kenjiro Teshima, Yasuo Shirai, and Tsutomu Miyasaka, “Organometal Halide Perovskites as Visible-Light Sensitizers for Photovoltaic Cells” and J. Am. Chem. Soc., 2009, 131 (17), 6050-6051 can also be exemplified.

The light absorber may be used in such an amount as to cover at least a part of a light incident surface among the surfaces of the porous layer 12 or the blocking layer 14, and is preferably used in such an amount as to cover the entire light incident surface.

<Solid Hole Transport Layer 3>

The solid hole transport layer (simply also referred to as hole transport layer) 3 is a solid-state layer having a function to replenish electrons to an oxidant of the light absorber. The hole transport layer 3 is preferably provided between the photosensitive layer 13 of the first electrode 1 and the second electrode 2.

The hole transport material which forms the hole transport layer 3 is not particularly limited, but examples thereof include inorganic materials such as CuI, CuNCS and organic hole transport materials described in paragraphs 0209 to 0212 of JP2001-291534A. Preferable examples of the organic hole transport material include conductive polymers such as polythiophene, polyaniline, polypyrrole, and polysilane, a spiro compound in which two rings share a central atom such as C and Si having a tetrahedral structure, an aromatic amine compound such as triarylamine, a triphenylene compound, a nitrogen-containing heterocyclic compound, and a liquid crystal cyano compound.

The hole transport material is preferably a solid-state organic hole transport material which can be applied in a solution state, and specific examples thereof include 2,2′,7,7′-tetrakis-(N,N-di-p-methoxyphenylamine)-9,9-spirobifluorene (also referred to as Spiro-OMeTAD), poly(3-hexylthiophene-2,5-diyl), 4-(diethylamino)benzaldehyde diphenyl hydrazone, and polyethylenedioxythiophene (PEDOT).

The thickness of the hole transport layer 3 is not particularly limited, but is preferably 50 μm or less, more preferably 1 nm to 10 μm, even more preferably 5 nm to 5 μm, and particularly preferably 10 nm to 1 μm. The thickness of the hole transport layer 3 corresponds to an average distance between the second electrode 2 and the surface of the porous layer 12 or the surface of the photosensitive layer 13. A cross-section of the photoelectric conversion element 10 is observed using a scanning electron microscope (SEM) or the like, and an average of the farthest distances in ten parts is obtained as the thickness in the same manner as in the case of the thickness of the porous layer 12.

In the invention, the total thickness of the porous layer 12, the photosensitive layer 13, and the hole transport layer 3 is not particularly limited, but is preferably 0.1 μm to 200 μm, more preferably 0.5 μm to 50 μm, and even more preferably 0.5 μm to 5 μm. The total thickness of the porous layer 12, the photosensitive layer 13, and the hole transport layer 3 can be measured in the same manner as in the case of the thickness of the porous layer 12.

<Second Electrode 2>

The second layer 2 functions as a cathode in a solar cell. The second electrode 2 is not particularly limited as long as it has conductive properties, and generally may have the same configuration as the conductive support 11. The support 11a is not essentially required when a sufficient strength is kept.

As the structure of the second electrode 2, a structure having a high current collection effect is preferred. In order to allow light to reach the photosensitive layer 13, at least one of the conductive support 11 and the second electrode 2 should be substantially transparent. In the solar cell of the invention, it is preferable that the conductive support 11 is transparent and solar light is made incident from the side of the support 11a. In this case, it is more preferable that the second electrode 2 has light reflection properties.

Examples of the material which forms the second electrode 2 include metals such as platinum (Pt), gold (Au), nickel (Ni), copper (Cu), silver (Ag), indium (In), ruthenium (Ru), palladium (Pd), rhodium (Rh), iridium (Ir), and osmium (Os), the above-described conductive metal oxides, and carbon materials. The carbon materials may be conductive materials formed by bonding carbon atoms to each other, and examples thereof include fullerene, carbon nano-tube, graphite, and graphene.

The second electrode 2 is preferably glass or plastic having a thin film (including thin film formed by deposition) of a metal or a conductive metal oxide, and particularly preferably glass having a gold or platinum thin film or glass on which platinum is deposited.

The thickness of the second electrode 2 is not particularly limited, and is preferably 0.01 μm to 100 μm, more preferably 0.01 μm to 10 μm, and particularly preferably 0.01 μm to 1 μm.

<Other Configurations>

In the invention, in order to prevent the contact between the first electrode 1 and the second electrode 2, a spacer or a separator can also be used in place of or together with the blocking layer 14.

In addition, a hole blocking layer may be provided between the second electrode 2 and the hole transport layer 3.

<<Solar Cell>>

For example, as shown in FIGS. 1 and 2, the solar cell of the invention is configured such that the photoelectric conversion element of the invention is allowed to work with respect to the external circuit 6. As the external circuit connected to the first electrode 1 (conductive support 11) and the second electrode 2, a known external circuit can be used with no particular limits.

Side surfaces of the solar cell of the invention are preferably sealed with a polymer, an adhesive, or the like in order to prevent deterioration and transpiration of the constituent materials.

The solar cell having the photoelectric conversion element of the invention applied thereto is not particularly limited, and examples thereof include solar cells described in KR10-1172374B and J. Phys. Chem. Lett., 2013, 4, 1532-1536.

As described above, the photoelectric conversion element and the perovskite-sensitized solar cell of the invention have a porous layer containing at least one of insulating material, and the voltage fluctuation between solar cells is small, whereby stable cell performance is exhibited.

<<Method of Manufacturing Photoelectric Conversion Element and Solar Cell>>

The photoelectric conversion element and the solar cell of the invention can be manufactured according to known manufacturing methods such as methods described in KR10-1172374B and J. Phys. Chem. Lett., 2013, 4, 1532-1536.

Hereinafter, a method of manufacturing the photoelectric conversion element and the solar cell of the invention will be simply described.

The blocking layer 14 and the porous layer 12 are formed on a surface of the conductive support 11, if desired.

The blocking layer 14 can be formed through, for example, a method including: applying a dispersion containing the above-described insulating substance or its precursor compound to the surface of the conductive support 11; and performing baking, a spray pyrolysis method, or the like.

The method of forming the porous layer 12 is not particularly limited, but examples thereof include a wet method, a dry method, and other methods (for example, method described in Chemical Review, vol. 110, p. 6595 (2010)). In these methods, baking is preferably performed for 10 minutes to 10 hours at a temperature of 100° C. to 800° C. after application of a dispersion (paste) containing a porous material dispersed therein to the surface of the conductive support 11. Accordingly, fine particles can be firmly adhered to each other.

When the baking is performed more than once, the temperature for baking other than final baking (temperature for baking other than final baking) may be lower than the temperature for final baking (final baking temperature). For example, when a titanium oxide paste is used, the temperature for baking other than final baking can be set within a range of 50° C. to 300° C. In addition, the final baking temperature can be set to be higher than the temperature for baking other than final baking within a range of 100° C. to 600° C. When a glass support is used as the support 11a, the baking temperature is preferably 60° C. to 500° C.

When the porous layer 12 is composed of a fine particle layer formed by accumulating two or more types of porous materials, the film formation can be performed through the above-described method using a dispersion containing two or more types of porous materials or a plurality of dispersions containing a porous material.

Particularly, when the porous layer 12 is formed by accumulating fine particles having the second porous material on the surface of the first porous material, the film formation can also be performed through the above-described method with a pre-prepared porous material having the second porous material on the surface of the first porous material, and can also be performed by accumulating the second porous material on the surface of a layer formed by accumulating the first porous material, that is, by accumulating the porous materials in order. For example, a layer can be formed by accumulating the first porous material through the above-described method, and then the second porous material can be accumulated thereon through a solution dipping method, an electric precipitation method, or the like. Specifically, in the solution dipping method, the conductive support 11 having a layer formed by accumulating the first porous material is dipped in or coated with a dispersion liquid obtained by dissolving the second porous material or its precursor compound (for example, alkoxide, inorganic compound, salt, complex, or the like) in a solvent, and is washed and dried if necessary. Then, baking is performed at a temperature of 600° C. or lower in the air.

The amount of the porous material or the first porous material applied per surface area of 1 m² of the support 11 when forming the porous layer 12 is not particularly limited as long as the above-described content ratio is satisfied, but for example, the amount is 0.5 g to 500 g, and preferably 5 g to 100 g.

In the porous layer 12, the content of the insulating material can be adjusted by changing the concentration of the dispersion, amount of the dispersion applied, or the number of times of application of the dispersion.

Next, the photosensitive layer 13 is provided.

First, a light absorber solution for forming a photosensitive layer is prepared. The light absorber solution contains MX₂ and AX which are raw materials of the perovskite compound. Here, A, M, and X are synonymous with A, M, and X of Formula (I).

Next, the prepared light absorber solution is applied to the surface of the porous layer 12 and dried. Accordingly, the perovskite compound is formed on the surface of the porous layer 12.

In this manner, the photosensitive layer 13 containing at least one of perovskite compound on the surface of the porous layer 12 is provided.

On the photosensitive layer 13 provided in this manner, a hole transport material solution containing a hole transport material is applied and dried to form the hole transport layer 3.

In the hole transport material solution, the concentration of the hole transport material is preferably 0.1 M (mol/L) to 1.0 M (mol/L) from the viewpoint of excellent coatability and easy intrusion up to the inside of the holes of the porous layer 12 when the porous layer 12 is provided.

After the formation of the hole transport layer 3, the second electrode 2 is formed to manufacture a photoelectric conversion element and a solar cell.

The thickness of each layer can be adjusted by appropriately changing the concentration and the number of times of application of each dispersion liquid or solution. For example, when the thick photosensitive layer 13B shown in FIG. 2 is provided, the dispersion liquid may be applied and dried a plurality of times.

The above-described respective dispersion liquids and solutions may contain additives such as a dispersion auxiliary agent and a surfactant if necessary.

Examples of the solvent or dispersion medium used in the method of manufacturing the photoelectric conversion element and the solar cell include solvents described in JP2001-291534A, but the solvent or dispersion medium is not particularly limited thereto. In the invention, an organic solvent is preferred, and an alcohol solvent, an amide solvent, a nitrile solvent, a hydrocarbon solvent, a lactone solvent, and a mixed solvent of two or more thereof are more preferred. The mixed solvent is preferably a mixed solvent of solvents selected from an alcohol solvent, an amide solvent, a nitrile solvent, and a hydrocarbon solvent. Specifically, methanol, ethanol, γ-butyrolactone, chlorobenzene, acetonitrile, dimethylformamide (DMF), dimethylacetamide, or a mixed solvent thereof is preferred.

The method of applying the solution or dispersing agent which forms each layer is not particularly limited, and known methods such as spin coating, extrusion die coating, blade coating, bar coating, screen printing, stencil printing, roll coating, curtain coating, spray coating, dip coating, ink jet printing, and dipping can be used. Among these, spin coating, screen printing, dipping, and the like are preferred.

The solar cell is manufactured by connecting an external circuit to the first electrode 1 and the second electrode 2 of the photoelectric conversion element produced as described above.

### EXAMPLES

Hereinafter, the invention will be described in more detail based on the following examples, but is not limited thereto.

### Example 1

The photoelectric conversion element 10A and the solar cell shown in FIG. 1 were manufactured according to the following procedures. When the photosensitive layer 13 has a large thickness, the large thickness is provided to correspond to the photoelectric conversion element 10B and the solar cell shown in FIG. 2.

The porous material used in each example was used as an insulating material or a semiconductive porous material relative to the energy level of the lowest unoccupied molecular orbital (LUMO) of the perovskite compound.

The energy level (−3.9 eV) of the lowest unoccupied molecular orbital (LUMO) of the perovskite compound (CH₃NH₃PbI₃) was calculated using the method described in Nanoscale Research Letters, 2012, 7: 353. The energy levels of LUMOs of the perovskite compounds calculated in the same manner are as follows: CH₃NH₃PbBr₃ (−3.4 eV), [CH(═NH)NH₃]PbI₃ (−4.0 eV), and (CH₃CH₂NH₃)₂PbI₄ (−3.4 eV).

The following energy levels of the porous materials were calculated from the values described in both the documents. Specific values are as follows.

Insulating Material: zirconium dioxide (energy level of conduction band: −3.1 eV to −3.2 eV), aluminum oxide (energy level of conduction band: −1.0 eV to 0.0 eV), and silicon dioxide (energy level of conduction band: −1.0 eV to 0.0 eV)

Semiconductive Porous Material: titanium oxide (energy level of conduction band: −4.0 eV to −4.2 eV), zinc oxide (energy level of conduction band: −3.9 eV to −4.1 eV), and tin oxide (energy level of conduction band: −4.3 eV to −4.5 eV)

These values are values (vs. NHE) converted into normal hydrogen electrode (NHE) scale.

(Manufacturing of Photoelectric Conversion Elements and Solar Cells (Sample Nos. 101 to 106))

First, photoelectric conversion elements and solar cells (Sample Nos. 101 to 106) having a porous layer 12 (porous layer aspect B) formed by accumulating two types of porous materials (insulating material and semiconductive porous material) in a mixed state, a light absorber A: CH₃NH₃PbBr₃, and a solid electrolyte were manufactured.

(Manufacturing of Photoelectric Conversion Element and Solar Cell (Sample No. 101))

<Formation of Blocking Layer 14>

A 15 mass % isopropanol solution of titanium diisopropoxide bis(acetylacetonato) (manufactured by Sigma-Aldrich Co. LLC.) was diluted with 1-butanol to prepare a 0.02 M solution for a blocking layer.

A fluorine-doped, conductive SnO₂ film (transparent electrode 11b) was formed on a glass substrate (support 11a, thickness: 2.2 mm) to produce a conductive support 11. Using the prepared 0.02 M solution for a blocking layer, a blocking layer 14 (thickness: 50 nm) was formed on the conductive SnO₂ film at 450° C. through a spray pyrolysis method.

<Formation of Porous Layer 12>

A mixed paste A was prepared by adding ethyl cellulose, lauric acid, and terpineol to an ethanol dispersion liquid containing a zirconium dioxide (ZrO₂, average particle diameter: 30 nm, spherical shape) and a titanium oxide (TiO₂, anatase, average particle diameter: 25 nm, spherical shape) at a mass ratio (ZrO₂/TiO₂) of 3/97.

The prepared mixed paste A was applied to the blocking layer 14 through a screen printing method and was baked for 1 hour at 500° C. The application and the baking of the mixed paste A were performed a plurality of times to form a porous layer 12 (thickness: 0.6 μm). The baking was performed in a manner such that the baking other than final baking was performed at 130° C. and the final baking was performed at 500° C. for 1 hour.

<Formation of Photosensitive Layer 13A>

A 40% methanol solution of methylamine (27.86 mL) and an aqueous solution of 57 mass % of hydrogen bromide (hydrobromic acid, 30 mL) were stirred for 2 hours at 0° C. in a flask, and then concentrated to obtain a crude material of CH₃NH₃Br. The obtained crude material of CH₃NH₃Br was dissolved in ethanol and recrystallized with diethyl ether. The precipitated crystals were filtered and dried under reduced pressure for 24 hours at 60° C., and thus purified CH₃NH₃Br was obtained.

Next, the purified CH₃NH₃Br and PbBr₂ were stirred and mixed at a molar ratio of 2:1 for 12 hours at 60° C. in γ-butyrolactone, and then filtered by a polytetrafluoroethylene (PTFE) syringe filter to prepare a 40 mass % light absorber solution A.

The prepared light absorber solution A was applied to the porous layer 12 through a spin coating method (for 60 seconds at 2000 rpm, then for 60 seconds at 3000 rpm). The applied light absorber solution A was dried using a hot plate for 20 minutes at 100° C. to form a photosensitive layer 13A having a perovskite compound. The perovskite compound contained in the photosensitive layer 13A was CH₃NH₃PbBr₃ having an AMX₃ structure.

In this manner, a first electrode 1A was produced.

<Formation of Hole Transport Layer 3>

Spiro-OMeTAD (180 mg) as a solid hole transport material was dissolved in chlorobenzene (1 mL). To the obtained chlorobenzene solution, an acetonitrile solution (37.5 μL) prepared by dissolving lithium-bis(trifluoromethane sulfonyl)imide (170 mg) in acetonitrile (1 mL) and t-butylpyridine (TBP, 17.5 μL) were added and mixed, and thus a hole transport material solution was prepared.

Next, the prepared hole transport material solution was applied to the photosensitive layer 13A of the first electrode 1A through a spin coating method, and the applied hole transport material solution was dried to form a hole transport layer 3 (thickness: 0.1 μm).

<Production of Second Electrode 2>

A second electrode 2 (thickness: 0.2 μm) was produced by depositing gold on the hole transport layer 3 through a deposition method.

In this manner, the photoelectric conversion element and the solar cell of the invention (Sample No. 101) were manufactured.

(Manufacturing of Photoelectric Conversion Elements and Solar Cells (Sample Nos. 102 to 106))

The photoelectric conversion elements and the solar cells of the invention (Sample Nos. 102 to 106) were manufactured in the same manner as in the manufacturing of the photoelectric conversion element and the solar cell (Sample No. 101), except that in the manufacturing of the photoelectric conversion element and the solar cell (Sample No. 101), the following mixed pastes B to F were used in place of the mixed paste A.

<Mixed Paste B>

The mixed paste B was prepared in the same manner as in the case of the mixed paste A, except that in the preparation of the mixed paste A, an ethanol dispersion liquid containing a zirconium dioxide and a titanium oxide at a mass ratio of 5/95 was used.

<Mixed Paste C>

The mixed paste C was prepared in the same manner as in the case of the mixed paste A, except that in the preparation of the mixed paste A, an ethanol dispersion liquid containing a zirconium dioxide and a titanium oxide at a mass ratio of 25/75 was used.

<Mixed Paste D>

The mixed paste D was prepared in the same manner as in the case of the mixed paste A, except that in the preparation of the mixed paste A, an ethanol dispersion liquid containing a zirconium dioxide and a titanium oxide at a mass ratio of 50/50 was used.

<Mixed Paste E>

The mixed paste E was prepared in the same manner as in the case of the mixed paste A, except that in the preparation of the mixed paste A, an ethanol dispersion liquid containing a zirconium dioxide and a titanium oxide at a mass ratio of 75/25 was used.

<Mixed Paste F>

The mixed paste F was prepared in the same manner as in the case of the mixed paste A, except that in the preparation of the mixed paste A, an ethanol dispersion liquid containing a zirconium dioxide and a titanium oxide at a mass ratio of 95/5 was used.

(Manufacturing of Photoelectric Conversion Element and Solar Cell (Sample No. 107))

A photoelectric conversion element and a solar cell (Sample No. 107) having a porous layer 12 in a porous layer aspect B, a light absorber B: CH₃NH₃PbI₃, and a solid electrolyte were manufactured.

The photoelectric conversion element and the solar cell of the invention (Sample No. 107) were manufactured in the same manner as in the case of the photoelectric conversion element and the solar cell (Sample No. 103), except that in the manufacturing of the photoelectric conversion element and the solar cell (Sample No. 103), the following light absorber solution B was used in place of the light absorber solution A.

<Light Absorber Solution B>

A 40% methanol solution of methylamine (27.86 mL) and an aqueous solution of 57 mass % of hydrogen iodide (30 mL) were stirred for 2 hours at 0° C. in a flask, and then concentrated to obtain a crude material of CH₃NH₃I. The obtained crude material of CH₃NH₃I was dissolved in ethanol and recrystallized with diethyl ether. The precipitated crystals were filtered and dried under reduced pressure for 24 hours at 60° C., and thus purified CH₃NH₃I was obtained.

Next, the purified CH₃NH₃I and PbI₂ were stirred and mixed at a molar ratio of 2:1 for 12 hours at 60° C. in γ-butyrolactone, and then filtered by a polytetrafluoroethylene (PTFE) syringe filter to prepare a 40 mass % light absorber solution B.

(Manufacturing of Photoelectric Conversion Elements and Solar Cells (Sample Nos. 108 to 111))

Next, photoelectric conversion elements and solar cells (Sample Nos. 108 to 111) having a porous layer 12 (porous layer aspect C) formed by accumulating a first porous material and a second porous material in a state in which the second porous material was adhered to (covered) a fine particle surface of the first porous material in the form of a film, a light absorber A, and a solid electrolyte were manufactured.

(Manufacturing of Photoelectric Conversion Element and Solar Cell (Sample No. 108))

The photoelectric conversion element and the solar cell of the invention (Sample No. 108) were manufactured in the same manner as in the case of the photoelectric conversion element and the solar cell (Sample No. 101), except that in the manufacturing of the photoelectric conversion element and the solar cell (Sample No. 101), the porous layer 12 was formed as follows.

<Formation of Porous Layer 12>

First, a titanium oxide paste was prepared by adding ethyl cellulose, lauric acid, and terpineol to an ethanol dispersion liquid of titanium oxide (TiO₂, anatase, average particle diameter: 20 nm, spherical shape) as a first porous material.

Next, the prepared titanium oxide paste was applied to the blocking layer 14 of the conductive support 11 prepared in the same manner as in the case of the photoelectric conversion element and the solar cell (Sample No. 101) through a screen printing method, and was baked. The application and the baking of the titanium oxide paste were performed a plurality of times. The baking other than final baking was performed at 130° C., and the final baking was performed at 500° C. for 1 hour. The obtained baked body of titanium oxide was dipped in a 40 mM TiCl₄ aqueous solution. Then, it was heated at 60° C. for 1 hour and was then heated at 500° C. for 30 minutes. Thus, a fine particle layer formed by accumulating the first porous material (TiO₂) was formed.

Next, this fine particle layer was dipped in a propanol solution of Zr (OC₄H₉)₄ at a concentration of 40 mM, and then washed with an ethanol solution and baked at 450° C. for 30 minutes under the atmosphere. In this manner, the surface of the fine particle layer (TiO₂) was covered with the insulating material (ZrO₂) as the second porous material, and thus the porous layer 12 was formed.

(Manufacturing of Photoelectric Conversion Elements and Solar Cells (Sample Nos. 109 and 110))

The photoelectric conversion elements and the solar cells of the invention (Sample Nos. 109 and 110) were manufactured in the same manner as in the case of the photoelectric conversion element and the solar cell (Sample No. 108), except that in the manufacturing of the photoelectric conversion element and the solar cell (Sample No. 108), the number of times of performing the application or dipping and the baking of the titanium oxide paste and the propanol solution of Zr(OC₄H₉)₄ was changed to adjust the content ratios of the titanium oxide and the zirconium dioxide.

(Manufacturing of Photoelectric Conversion Element and Solar Cell (Sample No. 111))

The photoelectric conversion element and the solar cell of the invention (Sample No. 111) were manufactured in the same manner as in the case of the photoelectric conversion element and the solar cell (Sample No. 101), except that in the manufacturing of the photoelectric conversion element and the solar cell (Sample No. 101), the porous layer 12 was formed as follows.

<Formation of Porous Layer 12>

A zirconium dioxide paste was prepared by adding ethyl cellulose, lauric acid, and terpineol to an ethanol dispersion liquid of zirconium dioxide (ZrO₂, average particle diameter: 30 nm, spherical shape) as a first porous material.

Next, the prepared zirconium dioxide paste was applied to the blocking layer 14 of the conductive support 11 prepared in the same manner as in the case of the photoelectric conversion element and the solar cell (Sample No. 101) through a screen printing method, and was baked. Regarding the baking, the baking other than final baking was performed at 130° C., and the final baking was performed at 500° C. for 1 hour. By changing the number of times of application and the number of times of baking of the zirconium dioxide paste, a fine particle layer formed by accumulating the first porous material (ZrO₂) was formed.

Next, this fine particle layer was dipped for 30 minutes in a TiCl₄ aqueous solution at a concentration of 40 mM, and then washed with pure water and baked at 500° C. for 30 minutes. In this manner, the surface of the fine particle layer (ZrO₂) was covered with the porous material (TiO₂) as the second porous material, and thus the porous layer 12 was formed.

(Manufacturing of Photoelectric Conversion Element and Solar Cell (Sample No. 112))

A photoelectric conversion element and a solar cell (Sample No. 112) having a porous layer 12 in a porous layer aspect C, a light absorber B, and a solid electrolyte were manufactured.

The photoelectric conversion element and the solar cell of the invention (Sample No. 112) were manufactured in the same manner as in the case of the photoelectric conversion element and the solar cell (Sample No. 110), except that in the manufacturing of the photoelectric conversion element and the solar cell (Sample No. 110), the light absorber solution B was used in place of the light absorber solution A.

(Manufacturing of Photoelectric Conversion Element and Solar Cell (Sample No. 113))

A photoelectric conversion element and a solar cell (Sample No. 113) having a porous layer 12 (porous layer aspect B) formed by accumulating two types of porous materials (insulating materials) in a mixed state, a light absorber B, and a solid electrolyte were manufactured.

The photoelectric conversion element and the solar cell of the invention (Sample No. 113) were manufactured in the same manner as in the case of the photoelectric conversion element and the solar cell (Sample No. 101), except that in the manufacturing of the photoelectric conversion element and the solar cell (Sample No. 101), the following mixed paste G was used in place of the mixed paste A, and the light absorber solution B was used in place of the light absorber solution A.

<Mixed Paste G>

The mixed paste G was prepared by adding ethyl cellulose, lauric acid, and terpineol to an ethanol dispersion liquid containing a zirconium dioxide (ZrO₂, average particle diameter: 30 nm) and an aluminum oxide (Al₂O₃, average particle diameter: 30 nm, spherical shape) at a mass ratio (ZrO₂/Al₂O₃) of 50/50.

(Manufacturing of Photoelectric Conversion Elements and Solar Cells (Sample Nos. 114 to 116))

Photoelectric conversion elements and solar cells (Sample Nos. 114 to 116) having a porous layer 12 in a porous layer aspect C, a light absorber B, and a solid electrolyte were manufactured.

(Manufacturing of Photoelectric Conversion Element and Solar Cell (Sample No. 114))

The photoelectric conversion element and the solar cell of the invention (Sample No. 114) were manufactured in the same manner as in the case of the photoelectric conversion element and the solar cell (Sample No. 109), except that in the manufacturing of the photoelectric conversion element and the solar cell (Sample No. 109), an ethanol/water mixed solution of Si(OC₂H₅)₄ was used in place of the propanol solution of Zr(OC₄H₉)₄, and the light absorber solution B was used in place of the light absorber solution A.

The number of times of performing the application or dipping and the baking of the ethanol/water mixed solution of Si(OC₂H₅)₄ and the number of times of performing the application and the baking of the titanium oxide paste were changed to adjust the content ratios of the silicon dioxide and the titanium oxide.

(Manufacturing of Photoelectric Conversion Element and Solar Cell (Sample No. 115))

The photoelectric conversion element and the solar cell of the invention (Sample No. 115) were manufactured in the same manner as in the case of the photoelectric conversion element and the solar cell (Sample No. 114), except that in the manufacturing of the photoelectric conversion element and the solar cell (Sample No. 114), an alcohol solution of Al(OiC₃H₇)₃ was used in place of the ethanol/water mixed solution of Si(OC₂H₅)₄.

The number of times of performing the application and the baking of the alcohol solution of Al(OiC₃H₇)₃ and the number of times of performing the application and the baking of the titanium oxide paste were changed to adjust the content ratios of the aluminum oxide and the titanium oxide.

(Manufacturing of Photoelectric Conversion Element and Solar Cell (Sample No. 116))

The photoelectric conversion element and the solar cell of the invention (Sample No. 116) were manufactured in the same manner as in the case of the photoelectric conversion element and the solar cell (Sample No. 109), except that in the manufacturing of the photoelectric conversion element and the solar cell (Sample No. 109), the light absorber solution B was used in place of the light absorber solution A.

(Manufacturing of Photoelectric Conversion Elements and Solar Cells (Sample Nos. 117 to 119))

Photoelectric conversion elements and solar cells (Sample Nos. 117 to 119) having a porous layer 12 in a porous layer aspect B, a light absorber B, and a solid electrolyte were manufactured.

(Manufacturing of Photoelectric Conversion Element and Solar Cell (Sample No. 117))

The photoelectric conversion element and the solar cell of the invention (Sample No. 117) were manufactured in the same manner as in the case of the photoelectric conversion element and the solar cell (Sample No. 102), except that in the manufacturing of the photoelectric conversion element and the solar cell (Sample No. 102), the light absorber solution B was used in place of the light absorber solution A.

(Manufacturing of Photoelectric Conversion Elements and Solar Cells (Sample Nos. 118 and 119))

The photoelectric conversion elements and the solar cells of the invention (Sample Nos. 118 and 119) were manufactured in the same manner as in the case of the photoelectric conversion element and the solar cell (Sample No. 102), except that in the manufacturing of the photoelectric conversion element and the solar cell (Sample No. 102), the following mixed paste H or I was used in place of the mixed paste B, and the light absorber solution B was used in place of the light absorber solution A.

<Mixed Paste H>

The mixed paste H was prepared by adding ethyl cellulose, lauric acid, and terpineol to an ethanol dispersion liquid containing a zirconium dioxide (ZrO₂, average particle diameter: 30 nm, spherical shape) and a zinc oxide (ZnO, average particle diameter: 30 nm, spherical shape) at a mass ratio (ZrO₂/ZnO) of 5/95.

<Mixed Paste I>

The mixed paste I was prepared by adding ethyl cellulose, lauric acid, and terpineol to an ethanol dispersion liquid containing a silicon dioxide (SiO₂, average particle diameter: 30 nm, spherical shape) and titanium oxide (TiO₂, anatase, average particle diameter: 25 nm, spherical shape) at a mass ratio (SiO₂/TiO₂) of 5/95.

(Manufacturing of Photoelectric Conversion Elements and Solar Cells (Sample Nos. 120 to 123))

Photoelectric conversion elements and solar cells (Sample Nos. 120 to 123) having a porous layer 12 in a porous layer aspect C, a light absorber B, and a solid electrolyte were manufactured.

(Manufacturing of Photoelectric Conversion Elements and Solar Cells (Sample Nos. 120 and 121))

The photoelectric conversion elements and the solar cells of the invention (Sample Nos. 120 and 121) were manufactured in the same manner as in the case of the photoelectric conversion element and the solar cell (Sample No. 111), except that in the manufacturing of the photoelectric conversion element and the solar cell (Sample No. 111), the following aluminum oxide paste was used in place of the zirconium dioxide paste, the following zinc oxide paste or the following tin dioxide paste was used in place of the titanium oxide paste, and the light absorber solution B was used in place of the light absorber solution A.

<Aluminum Oxide Paste>

The aluminum oxide paste was prepared by adding ethyl cellulose, lauric acid, and terpineol to an ethanol dispersion liquid of aluminum oxide (Al₂O₃, average particle diameter: 30 nm, spherical shape).

<Zinc Oxide Paste>

The zinc oxide paste was prepared by adding ethyl cellulose, lauric acid, and terpineol to an ethanol dispersion liquid of zinc oxide (ZnO, average particle diameter: 30 nm, spherical shape).

<Tin Dioxide Paste>

The tin dioxide paste was prepared by adding ethyl cellulose, lauric acid, and terpineol to an ethanol dispersion liquid of tin dioxide (SnO₂, average particle diameter: 30 nm, spherical shape).

(Manufacturing of Photoelectric Conversion Elements and Solar Cells (Sample Nos. 122 and 123))

The photoelectric conversion elements and the solar cells of the invention (Sample Nos. 122 and 123) were manufactured in the same manner as in the case of the photoelectric conversion element and the solar cell (Sample No. 111), except that in the manufacturing of the photoelectric conversion element and the solar cell (Sample No. 111), the aluminum oxide paste (see Sample No. 121) or the following silicon dioxide paste was used in place of the zirconium dioxide paste, and the light absorber solution B was used in place of the light absorber solution A.

<Silicon Dioxide Paste>

The silicon dioxide paste was prepared by adding ethyl cellulose, lauric acid, and terpineol to an ethanol dispersion liquid of silicon dioxide (SiO₂, average particle diameter: 30 nm, spherical shape).

(Manufacturing of Photoelectric Conversion Element and Solar Cell (Sample No. 124))

A photoelectric conversion element and a solar cell (Sample No. 124) having a porous layer 12 in a porous layer aspect B, a light absorber C: [CH(═NH)NH₃]PbI₃, and a solid electrolyte were manufactured.

The photoelectric conversion element and the solar cell of the invention (Sample No. 124) were manufactured in the same manner as in the case of the photoelectric conversion element and the solar cell (Sample No. 102), except that in the manufacturing of the photoelectric conversion element and the solar cell (Sample No. 102), the following light absorber solution C was used in place of the light absorber solution A, and the light absorber solution C applied to the porous layer 12 was dried for 40 minutes at 160° C.

The perovskite compound contained in the photosensitive layer 13A of the photoelectric conversion element and the solar cell (Sample No. 124) was [CH(═NH)NH₃]PbI₃ having an AMX₃ structure.

<Light Absorber Solution C>

Formamidine acetate and an aqueous solution of 57 mass % of hydrogen iodide, containing the hydrogen iodide 2 eq. based on the formamidine acetate, were stirred for 1 hour at 0° C. in a flask, and then further stirred and mixed for 1 hour after the temperature was raised to 50° C. The obtained solution was concentrated to obtain a crude material of formamidine-hydrogen iodate. The obtained crude material was recrystallized with diethyl ether, and the precipitated crystals were filtered and dried under reduced pressure for 10 hours at 50° C. Thus, purified formamidine-hydrogen iodate was obtained.

Next, the purified formamidine-hydrogen iodate and PbI₂ were stirred and mixed at a molar ratio of 2:1 for 3 hours at 60° C. in dimethylformamide (DMF), and then filtered by a polytetrafluoroethylene (PTFE) syringe filter to prepare a 40 mass % light absorber solution C.

(Manufacturing of Photoelectric Conversion Element and Solar Cell (Sample No. 125))

A photoelectric conversion element and a solar cell (Sample No. 125) having a porous layer 12 in a porous layer aspect B, a light absorber D: (CH₃CH₂NH₃)₂PbI₄, and a solid electrolyte were manufactured.

The photoelectric conversion element and the solar cell of the invention (Sample No. 125) were manufactured in the same manner as in the case of the photoelectric conversion element and the solar cell (Sample No. 102), except that in the manufacturing of the photoelectric conversion element and the solar cell (Sample No. 102), the following light absorber solution D was used in place of the light absorber solution A, and the light absorber solution D applied on the porous layer 12 was dried for 40 minutes at 140° C.

The perovskite compound contained in the photosensitive layer of the photoelectric conversion element and the solar cell (Sample No. 125) was (CH₃CH₂NH₃)₂PbI₄ having an A₂MX₄ structure.

<Light Absorber Solution D>

The light absorber solution D was prepared in the same manner as in the preparation of the light absorber solution B, except that in the preparation of the light absorber solution B, ethylamine was used in place of the 40% methanol solution of methylamine, and the molar ratio between the obtained, purified CH₃CH₂NH₃I and PbI₂ was changed to 3:1.

(Manufacturing of Photoelectric Conversion Element and Solar Cell (Sample No. c101))

A photoelectric conversion element and a solar cell (Sample No. c101) having a porous layer (porous layer aspect A) formed by accumulating one of semiconductive porous material, a light absorber A, and a solid electrolyte were manufactured.

The photoelectric conversion element and the solar cell for comparison (Sample No. c101) were manufactured in the same manner as in the case of the photoelectric conversion element and the solar cell (Sample No. 101), except that in the manufacturing of the photoelectric conversion element and the solar cell (Sample No. 101), the porous layer was formed using the titanium oxide paste prepared in the manufacturing of the photoelectric conversion element and the solar cell (Sample No. 108) in place of the mixed paste A.

Specifically, the titanium oxide paste was applied to the blocking layer 14 through a screen printing method, and was baked. The application and the baking of the titanium oxide paste were performed a plurality of times. The baking other than final baking was performed at 130° C., and the final baking was performed at 500° C. for 1 hour. The obtained baked body of titanium oxide was dipped in a 40 mM TiCl₄ aqueous solution. Then, it was heated at 60° C. for 1 hour and was then heated at 500° C. for 30 minutes. Thus, a porous layer formed of the porous material (TiO₂) was formed.

(Manufacturing of Photoelectric Conversion Element and Solar Cell (Sample No. c102))

A photoelectric conversion element and a solar cell (Sample No. c102) having a porous layer in a porous layer aspect B, a light absorber B, and a liquid electrolyte were manufactured.

The photoelectric conversion element and the solar cell for comparison (Sample No. c102) were manufactured in the same manner as in the case of the photoelectric conversion element and the solar cell (Sample No. 107), except that in the manufacturing of the photoelectric conversion element and the solar cell (Sample No. 107), an ethyl acetate solution (solvent: ethyl acetate) obtained by mixing LiI, I₂, t-butylpyridine (TBP), and urea was used as the electrolyte solution in place of the hole transport material solution containing Spiro-OMeTAD (180 mg), and the second electrode 2 was formed of platinum.

(Manufacturing of Photoelectric Conversion Element and Solar Cell (Sample No. c103))

A photoelectric conversion element and a solar cell (Sample No. c103) having a porous layer (porous layer aspect A) formed by accumulating one of insulating material, a light absorber B, and a liquid electrolyte were manufactured.

The photoelectric conversion element and the solar cell for comparison (Sample No. c103) were manufactured in the same manner as in the case of the photoelectric conversion element and the solar cell (Sample No. 101), except that in the manufacturing of the photoelectric conversion element and the solar cell (Sample No. 101), the porous layer was formed using the zirconium dioxide paste prepared in the manufacturing of the photoelectric conversion element and the solar cell (Sample No. 111) in place of the mixed paste A, the light absorber solution B was used in place of the light absorber solution A, an ethyl acetate solution (solvent: ethyl acetate) obtained by mixing LiI, I₂, t-butylpyridine (TBP), and urea was used as the electrolyte solution in place of the hole transport material solution containing Spiro-OMeTAD (180 mg), and the second electrode 2 was formed of platinum.

(Content Ratio of Insulating Material in Porous Layer)

In the manufactured solar cells (Sample Nos. 101 to 125 and c101 to c103), the content ratio of the insulating material in the porous layer (mass of insulating material/(mass of insulating material+mass of porous material)×100(%)) was calculated as follows. The results are shown as “Content Ratio (wt %)” in Table 1.

Regarding the solar cells (Sample Nos. 101 to 107, 113, 117 to 119, 124, 125, and c101 to c103), the content ratio of the insulating material in each paste or dispersion liquid forming the porous layer (mass of insulating material/(mass of insulating material+mass of semiconductive porous material)) was calculated and set as the content ratio (mass %) of the insulating material in the porous layer.

Regarding the solar cells (Sample Nos. 108 to 112, 114 to 116, and 120 to 123), ten samples each having a fine particle layer formed by accumulating the first porous material using the same method were prepared separately from the manufacturing of the photoelectric conversion element and the solar cell, a mass change before and after the film formation was measured, and a difference thereof was set as the mass of the first porous material. Next, after the fine particle surface was covered with the second porous material, a mass change was measured in the same manner, and a difference thereof was set as the mass of the second porous material. From the obtained mass, the content ratio of the insulating material in the porous layer (mass of insulating material/(mass of insulating material+mass of semiconductive porous material) (mass %) was obtained. The organic matter used in the paste was judged to be removed in the course of baking.

(Evaluation of Fluctuation in Voltage)

The fluctuation in the voltage was evaluated as follows for each of the sample Nos. of the solar cells.

That is, for each sample No., ten solar cell samples were manufactured in the same manner as in the manufacturing method, and each of the ten samples was subjected to a cell characteristic test to measure a voltage. The cell characteristic test was performed by applying 1000 W/m² of artificial solar light passing through an AM 1.5 filter from a xenon lamp using a solar simulator “WXS-85H” (manufactured by Wacom Co., Ltd.). The voltage was measured using an I-V tester.

An average of the voltages obtained as described above was calculated. This average was set to “1”, and a voltage (relative value) of each of the ten solar cell samples with respect to the average “1” was obtained.

For the evaluation, the ten solar cell samples were classified into two groups consisting of a group in which the obtained voltage (relative value) was not less than the average “1” (referred to as “high side”) and a group in which the obtained voltage was less than the average “1” (referred to as “low side”). For the evaluation, a difference (absolute value) between the voltage (relative value) of each of the samples belonging to each group and the average “1” was calculated, and the fluctuation in the voltage was evaluated based on the following evaluation standards. Specifically, a sample having the largest difference in each group was evaluated to know which one of the ranges of the following evaluation standards the sample belongs to.

In the invention, when the evaluation of the fluctuation in the voltage is at a level C or higher, the target level is achieved. In practical use, the level is preferably C+ or higher, and more preferably A or B.

(Evaluation Standards)

A: 0 to 0.07

B: greater than 0.07 to 0.10

C+: greater than 0.10 to 0.13

C: greater than 0.13 to 0.16

D: greater than 0.16

TABLE 1

| | | | Porous | | | | | Evaluation of | | |
|---|---|---|---|---|---|---|---|---|---|---|
| | | | Layer | Second | | Light | | Fluctuation | | |
| Sample | Insulating | Semiconductive | Aspect | Porous | Content | Absorber | Electrolyte | in Voltage | | |
| No. | Material | Porous Material | (*1) | Material | (wt %) | (*2) | (*3) | High Side | Low Side | Remarks |
| c101 | None | TiO₂ | A | — | — | A | A | D | D | Comparative Example |
| 101 | ZrO₂ | TiO₂ | B | — | 3 | A | A | C | C | Example |
| 102 | ZrO₂ | TiO₂ | B | — | 5 | A | A | B | B | Example |
| 103 | ZrO₂ | TiO₂ | B | — | 25 | A | A | B | B | Example |
| 104 | ZrO₂ | TiO₂ | B | — | 50 | A | A | B | B | Example |
| 105 | ZrO₂ | TiO₂ | B | — | 75 | A | A | C | C | Example |
| 106 | ZrO₂ | TiO₂ | B | — | 95 | A | A | C | C | Example |
| 107 | ZrO₂ | TiO₂ | B | — | 25 | B | A | B | B | Example |
| 108 | ZrO₂ | TiO₂ | C | ZrO₂ | 3 | A | A | B | B | Example |
| 109 | ZrO₂ | TiO₂ | C | ZrO₂ | 5 | A | A | A | A | Example |
| 110 | ZrO₂ | TiO₂ | C | ZrO₂ | 25 | A | A | A | A | Example |
| 111 | ZrO₂ | TiO₂ | C | TiO₂ | 75 | A | A | C+ | C+ | Example |
| 112 | ZrO₂ | TiO₂ | C | ZrO₂ | 25 | B | A | A | A | Example |
| 113 | ZrO₂ | None | B | — | 100 | B | A | C | C | Example |
| | Al₂O₃ | | | | | | | | | |
| 114 | SiO₂ | TiO₂ | C | SiO₂ | 5 | B | A | B | B | Example |
| 115 | Al₂O₃ | TiO₂ | C | Al₂O₃ | 5 | B | A | B | A | Example |
| 116 | ZrO₂ | TiO₂ | C | ZrO₂ | 5 | B | A | A | A | Example |
| 117 | ZrO₂ | TiO₂ | B | — | 5 | B | A | B | B | Example |
| 118 | ZrO₂ | ZnO | B | — | 5 | B | A | B | B | Example |
| 119 | SiO₂ | TiO₂ | B | — | 5 | B | A | B | C+ | Example |
| 120 | Al₂O₃ | ZnO | C | ZnO | 75 | B | A | C+ | C | Example |
| 121 | Al₂O₃ | SnO₂ | C | SnO₂ | 75 | B | A | C+ | C | Example |
| 122 | Al₂O₃ | TiO₂ | C | TiO₂ | 75 | B | A | C+ | C | Example |
| 123 | SiO₂ | TiO₂ | C | TiO₂ | 75 | B | A | C+ | C | Example |
| 124 | ZrO₂ | TiO₂ | B | — | 5 | C | A | B | B | Example |
| 125 | ZrO₂ | TiO₂ | B | — | 5 | D | A | B | B | Example |
| c102 | ZrO₂ | TiO₂ | B | — | 25 | B | B | D | D | Comparative Example |
| c103 | ZrO₂ | None | A | — | 100 | B | B | D | D | Comparative Example |

(*1) In Table 1, the porous layer aspect A represents an aspect in which the porous layer is formed by accumulating one of the semiconductive porous material and the insulating material. The porous layer aspect B represents an aspect in which the porous layer is formed by accumulating two materials, that is, the semiconductive porous material and the insulating material, or by accumulating two types of insulating materials. The porous layer aspect C represents an aspect in which the porous layer is formed by adhering the second porous material to a fine particle surface of the first porous material in the form of a film (by covering a fine particle surface of the first porous material with the second porous material).
(*2) In Table 1, the light absorber A represents CH₃NH₃PbBr₃, the light absorber B represents CH₃NH₃PbI₃, the light absorber C represents [CH(═NH)NH₃]PbI₃, and the light absorber D represents (CH₃CH₂NH₃)₂PbI₄,
(*3) In Table 1, the electrolyte A represents a solid electrolyte, and the electrolyte B represents a liquid electrolyte.

As shown in Table 1, all of the solar cells (Sample Nos. 101 to 125) having a porous layer containing at least one of insulating material were found to have less fluctuation in the voltage.

In addition, it was found that when the porous layer contains two types of materials consisting of the semiconductive porous material and the insulating material, the fluctuation in the voltage is further reduced. Moreover, it was found that when the porous layer has a coating of the second porous material on the fine particle surface of the first porous material (porous layer aspect C), particularly, when the coating of the second porous material is formed by the insulating material, the effect of suppressing the voltage fluctuation is significant.

Furthermore, it was found that when the content ratio of the insulating material in the porous layer is 5 mass % to 95 mass %, and particularly, 5 mass % to 50 mass % in any porous layer aspect, the effect of suppressing the fluctuation in the voltage is enhanced.

The solar cell (Sample No. c101) having a porous layer formed of one of semiconductive porous material had a great fluctuation in the voltage. In addition, it was found that when having a liquid electrolyte (Sample Nos. c102 and c103), the solar cells do not exhibit the voltage fluctuation suppression effect even when the porous layer contains an insulating material.

### EXPLANATION OF REFERENCES

1A, 1B: first electrode
11: conductive support
11a: support
11b: transparent electrode
12: porous layer
13A, 13B: photosensitive layer
14: blocking layer
2: second electrode
3A, 3B: hole transport layer
6: external circuit (lead)
10A, 10B: photoelectric conversion element
100A, 100B: system in which photoelectric conversion element is applied for use in cell
M: electric motor

What is claimed is:

1. A photoelectric conversion element comprising:
a first electrode which has a porous layer provided on a conductive support and a photosensitive layer having a light absorber on a surface of the porous layer;
a second electrode which is opposed to the first electrode; and
a solid hole transport layer which is provided between the first electrode and the second electrode,
wherein the light absorber includes a compound having a perovskite crystal structure having a cation of a group I element of the periodic table or a cation of a cationic organic group A, a cation of a metal atom M other than the group I elements of the periodic table, and an anion of an anionic atom X, and
the porous layer contains at least one of insulating material and at least one of porous material different from the insulating material.

2. The photoelectric conversion element according to claim 1,
wherein the insulating material is contained in the porous layer in an amount of 5 mass % to 95 mass %.

3. The photoelectric conversion element according to claim 1,
wherein the insulating material is contained in the porous layer in an amount of 5 mass % to 50 mass %.

4. The photoelectric conversion element according to claim 1,
wherein the porous layer contains the insulating material and the porous material different from the insulating material, and
wherein, on a surface of one of the insulating material or the porous material, the other of the insulating material or the porous material is disposed.

5. The photoelectric conversion element according to claim 1,
wherein the porous layer has the insulating material on a surface of the porous material different from the insulating material.

6. The photoelectric conversion element according to claim 4,
wherein at least a part of the surface of the one of the insulating material or the porous material is covered with the other of the insulating material or the porous material.

7. The photoelectric conversion element according to claim 1,
wherein one of the insulating material and one of the porous material different from the insulating material are contained.

8. The photoelectric conversion element according to claim 1,
wherein the insulating material is selected from the group consisting of oxides of zirconium, aluminum, and silicon.

9. The photoelectric conversion element according to claim 1,
wherein the porous material different from the insulating material is selected from the group consisting of oxides of titanium, zinc, tin, tungsten, zirconium, aluminum, and silicon, and a carbon nano-tube.

10. The photoelectric conversion element according to claim 1,
wherein the porous material different from the insulating material has a conduction band with an energy level that is the same as or lower than the lowest unoccupied molecular orbital of the perovskite light absorber.

11. The photoelectric conversion element according to claim 1,
wherein the insulating material is an oxide of zirconium or aluminum, and
the porous material different from the insulating material is an oxide of titanium, zinc, tin, or tungsten.

12. The photoelectric conversion element according to claim 1,
wherein the compound having a perovskite crystal structure is a compound represented by the following Formula (I),
AₐMₘXₓ Formula (I):
wherein A represents a group I element of the periodic table or a cationic organic group, M represents a metal atom other than the group I elements of the periodic table, X represents an anionic atom, a represents 1 or 2, m represents 1, and a, m, and x satisfy a+2 m=x.

13. The photoelectric conversion element according to claim 1,
wherein the compound having a perovskite crystal structure includes a compound represented by the following Formula (I-1),
AMX₃ Formula (I-1):
wherein A represents a group I element of the periodic table or a cationic organic group, M represents a metal atom other than the group I elements of the periodic table, and X represents an anionic atom.

14. The photoelectric conversion element according to claim 1,
wherein the compound having a perovskite crystal structure includes a compound represented by the following Formula (I-2),
A₂MX₄ Formula (I-2):
wherein A represents a group I element of the periodic table or a cationic organic group, M represents a metal atom other than the group I elements of the periodic table, and X represents an anionic atom.

15. The photoelectric conversion element according to claim 1,
wherein A is a cationic organic group represented by the following Formula (1),
R^{1a}—NH₃ Formula (1):
wherein R^{1a} represents a substituent.

16. The photoelectric conversion element according to claim 15,
wherein R^{1a} is an alkyl group, a cycloalkyl group, an alkenyl group, an alkynyl group, an aryl group, a heteroaryl group, or a group represented by the following Formula (2), 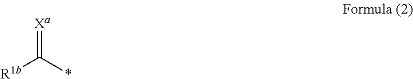
wherein X^{a} represents NR^{1c}, an oxygen atom, or a sulfur atom, each of R^{1b} and R^{1c} independently represents a hydrogen atom or a substituent, and * represents a bonding position with the N atom of Formula (1).

17. The photoelectric conversion element according to claim 1,
wherein X is a halogen atom.

18. The photoelectric conversion element according to claim 1,
wherein M is a Pb atom or a Sn atom.

19. A solar cell comprising:
the photoelectric conversion element according to claim 1.
